(19) United States
(12) Patent Application Publication
(10) Pub. No.: US 2025/0364890 A1
(43) Pub. Date: Nov. 27, 2025

(54) TECHNIQUES FOR ASSOCIATING A FEEDBACK PORT OR ELECTRICAL CONDUCTOR RESISTANCE WITH A DC OUTPUT PORT OF A VOLTAGE CONVERTER SYSTEM

(71) Applicant: Outdoor Wireless Networks LLC, Hickory, NC (US)

(72) Inventors: Jose Antonio Torres Rabello, Orland Park, IL (US); David Winkler, Alexandria, VA (US); Alessandro Sinicco, Monza (IT); Dale Moore, Sachse, TX (US); Simone Pedruzzi, Capriate San Gervasio (BG) (IT)

(73) Assignee: Outdoor Wireless Networks LLC, Claremont, NC (US)

(21) Appl. No.: 18/875,901

(22) PCT Filed: Jun. 6, 2023
(86) PCT No.: PCT/IT2023/000022

§ 371 Date: Dec. 17, 2024

(30) Foreign Application Priority Data
Jul. 1, 2022 (IT) 102022000014014
Oct. 6, 2022 (IT) 102022000020622
Jan. 12, 2023 (IT) 102023000000303

(51) Int. Cl. H02M 1/00; G01R 27/16; H02M 1/32; H02M 3/156

(52) U.S. Cl. CPC H02M 1/008; G01R 27/16; H02M 1/32; H02M 3/156

(57) ABSTRACT

Techniques are provided for correctly associating a feedback port of a DC-DC voltage converter system and a DC power output port of the DC-DC voltage converter system. By having a correct association, measurement data from a measurement sensor coupled through a set of electrical conductors to a DC-DC voltage converter are fed back to a processing system and used to control a DC voltage level provided by the DC-DC voltage converter to accurately regulate a DC voltage at radio ends of the set of electrical conductors. Alternatively, a resistance of the set of electrical conductors is determined using regression and without such association. Both the resistance and a measured current, drawn from a DC power output electrically and through first ends of the set of electrical conductors to the radio ends, can be used to accurately regulate the DC voltage at the radio ends.

### CROSS-REFERENCE TO RELATED APPLICATIONS

The present application claims priority to Italian Patent Application Serial No. 102022000014014, filed Jul. 1, 2022, of Italian Patent Application Serial No. 102022000020622, filed Oct. 6, 2022, and of Italian Patent Application Serial No. 102023000000303, filed Jan. 12, 2023; the entire contents of each of the aforementioned patent applications are incorporated herein by reference as if set forth in their entirety.

### BACKGROUND

A direct current (DC)-DC voltage converter may be used to boost its output voltage to diminish power dissipation in electrical conductors coupling an output of the DC-DC voltage converter to a DC power input of a radio. The DC-DC voltage converter provides DC electrical power to the radio through the electrical conductors. U.S. Pat. No. 9,448,576 (hereinafter the '576 Patent) describes different embodiments of voltage converter systems configured to accomplish this. The '576 Patent is incorporated by reference herein in its entirety.

First ends of the electrical conductors are configured to be electrically coupled to the DC-DC voltage converter. Radio ends of the electrical conductors are configured to be electrically coupled to the radio; the radio ends of the electrical conductors are remote from the DC-DC voltage converter.

In one embodiment described in the '576 Patent, a measurement sensor is configured to measure an electrical parameter at radio ends of the electrical conductors. Measurements from the measurement sensor are fed back to the DC-DC voltage converter. The measurements are used to adjust the voltage level at the output of the DC-DC voltage converter. For example, the measurements may be directly used in substantially real time to adjust such voltage level by comparing the measurements to a target (or a desired) DC voltage at the radio ends (“feedback approach”). Alternatively, for example, the measurements may be used to determine a resistance of the electrical conductors (“resistance calculation approach”). The resistance can be determined by determining a difference between a measured DC voltage level at the radio ends of the electrical conductors and a DC voltage at the output of the of the DC-DC voltage converter. The resistance equals the difference divided by a direct current drawn from the output of the DC-DC voltage converter. Once the resistance has been determined, a voltage level at the output of the DC-DC voltage converter which will maintain the target DC voltage at the radio ends can be determined by adding a product, of direct current drawn from the output of the DC-DC voltage converter and the resistance, to the target DC voltage at the radio ends.

A typical cellular base station includes multiple radios, and thus may utilize multiple DC-DC voltage converters. Each DC-DC voltage converter provides power to a unique set of one or more radios.

Each radio may consume different amounts of power during a period of time, e.g., due to different amounts of downlink traffic being transmitted by each radio during the time period. Thus, during the period of time, each DC-DC voltage converter may have to provide a differing amount of voltage boost.

In the feedback embodiment described above, an installer, of the DC-DC voltage converter system, forms a feedback connection between a measurement sensor (electrically coupled to a radio) and a first DC-DC voltage converter. However, the installer incorrectly connects electrical conductors between the measurement sensor and a second DC-DC voltage converter. In such event, incorrect or no feedback is provided to the second DC-DC voltage converter which can cause a DC voltage at the DC power input of the radio, electrically powered by the second DC-DC voltage converter, to be below or to exceed a DC voltage input range of the radio in which a DC voltage at the DC power input of the radio must be maintained for the radio to operate properly. If the first DC-DC voltage converter provides DC power to a DC power input of another radio, then incorrect feedback is provided to the first DC-DC voltage converter which can cause a DC voltage at a DC power input of the other radio to be below or to exceed a DC voltage input range of the radio in which the voltage at the DC power input of the other radio must be maintained for the other radio to operate properly.

As a result, the radio and/or the other radio may no longer operate properly and may even become damaged. In such event, the base station is unable to ensure continuity of communication services.

### SUMMARY

A method is provided for determining a resistance of at least two sets of electrical conductors each of which whose first ends are electrically coupled to a unique power output of a DC-DC voltage converter system and whose radio ends are electrically coupled to a DC power input of a unique radio. The method comprises: providing a constant direct current (DC) voltage level at each of at least two power output of the DC-DC voltage converter system; measuring, during a time period, a set of direct current levels drawn from each power output which provides a constant DC voltage level, and associating each set of direct current levels with a power output from which direct current was drawn; receiving, at each logical or physical data port of the DC-DC voltage converter system, a set of data indicative of voltage levels measured during the time period at radio ends of a unique set of electrical conductors through which DC electrical power is provided from one of the at least two power output and through the first ends to the radio ends of the unique set of electrical conductors; determining at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of direct current levels with respect to all sets of data indicative of voltage levels; and for each of the at least two pairs, performing linear regression on the unique set of direct current levels and the unique set of data indicative of voltage levels of a pair, and then determining, from a slope coefficient, or a magnitude thereof, derived from the linear regression, a resistance of a set of electrical conductors electrically coupled to a power output with which the unique set of direct current levels was drawn.

A non-transitory computer readable medium is provided which stores a program causing at least one processor to execute a process to determine a resistance of at least two sets of electrical conductors each of which whose first ends are electrically coupled to a unique power output of a DC-DC voltage converter system and whose radio ends are electrically coupled to a DC power input of a unique radio. The process comprises: causing provision of a constant direct current (DC) voltage level at each of at least two power output of the DC-DC voltage converter system; receiving a set of direct current levels measured during a time period and drawn from each power output which provides a constant DC voltage level, and associating each set of direct current levels with a power output from which direct current was drawn; receiving, from each logical or physical data port of the DC-DC voltage converter system, a set of data indicative of voltage levels measured during the time period at radio ends of a unique set of electrical conductors though which DC electrical power is provided from one of the at least two power output and through the first ends to the radio ends of the unique set of electrical conductors; determining at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of current levels with respect to all sets of data indicative of voltage levels; and for each of the at least two pairs, (a) performing linear regression on the unique set of direct current levels and the unique set of data indicative of voltage levels of a pair, and then (b) determining, from a slope coefficient, or a magnitude thereof, derived from the linear regression, a resistance of a set of electrical conductors electrically coupled to a power output with which the unique set of direct current levels was drawn.

A direct current (DC)-DC voltage converter system is provide that is configured to determine a resistance of at least two sets of electrical conductors each of which whose first ends are electrically coupled to a unique power output of the DC-DC voltage converter system and whose radio ends are electrically coupled to a DC power input of a unique radio. The DC-DC voltage converter system comprises: at least two DC power outputs each of which is configured to be coupled through unique electrical conductors, at radio ends of the unique electrical conductors, to a unique measurement sensor and electrically coupled to a unique radio; at least two DC-DC voltage converters each of which is configured to provide DC power to a unique DC power output of the at least two DC power outputs; at least two logical or physical feedback ports each of which is configured to be communicatively coupled to the unique measurement sensor; and processing circuitry communicatively coupled to each DC-DC voltage converter, and configured to: cause provision of a constant direct current (DC) voltage level at each of at least two DC power outputs; receive a set of direct current levels measured during a time period and drawn from each power output which provides a constant DC voltage level, and associating each set of direct current levels with a power output from which direct current was drawn; receive, from each logical or physical data port, a set of data indicative of voltage levels measured during the time period at radio ends of a unique set of electrical conductors through which DC electrical power is provided from one of the at least two power outputs and through the first ends to the radio ends of the unique set of electrical conductors; determine at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of current levels with respect to all sets of data indicative of voltage levels; and for each of the at least two pairs, (a) performing linear regression on the unique set of direct current levels and the unique set of data indicative of voltage levels of a pair, and then (b) determining, from a slope coefficient, or a magnitude thereof, derived from the linear regression, a resistance of a set of electrical conductors electrically coupled to a power output with which the unique set of direct current levels was drawn.

A method is provided for correctly associating a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system. The method comprises: providing, during a time period, electrical DC power, including a constant DC voltage level, at at least two DC power outputs of the DC-DC voltage converter system, wherein direct current levels drawn during the time period from each of the at least two DC power outputs is different than the direct current levels drawn during the time period from any of other of the at least two DC power outputs; receiving measurement data, measured during the time period, (a) at each of the at least two feedback ports, of the DC-DC voltage converter system, from a unique one of measurement sensors and (b) that is derived from a DC voltage level, measured by the unique one of the measurement sensors, proximate to radio ends of a unique set of electrical conductors; measuring, during the time period, the direct current levels drawn from each of the at least two DC power outputs of the DC-DC voltage converter system; and using the measurement data measured during the time period received at each of the at least two feedback ports and the direct current levels measured being drawn, during the time period, from each of the at least two DC power outputs, determining an association between each of the at least two DC power outputs and a unique one of the at least two feedback ports, wherein the at least two feedback ports are either logical feedback ports or physical feedback ports; wherein responsive to other measurement data received at one of the at least two feedback ports at another time, the association is configured to be used to adjust a DC voltage level provided by a DC-DC voltage converter to one of the at least two DC power outputs which has been associated with the one of the at least two feedback ports.

A non-transitory computer readable medium is provided and which stores a program causing at least one processor to execute a process to correctly associate a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system. The process comprises: causing, during a time period, provision of electrical DC power, including a constant DC voltage level, at at least two DC power outputs of the DC-DC voltage converter system, wherein direct current levels drawn during the time period from each of the at least two DC power outputs is different than the direct current levels drawn during the time period from any of other of the at least two DC power outputs; receiving measurement data, measured during the time period, (a) at each of the at least two feedback ports, of the DC-DC voltage converter system, from a unique one of measurement sensors and (b) that is derived from a DC voltage level, measured by the unique one of the measurement sensors, proximate to radio ends of a unique set of electrical conductors; receiving, during the time period, measurements of the direct current levels drawn from each of the at least two DC power outputs of the DC-DC voltage converter system; and using the measurement data measured during the time period received at each of the at least two feedback ports and the direct current levels measured being drawn, during the time period, from each of the at least two DC power outputs, determining an association between each of the at least two DC power outputs and a unique one of the at least two feedback ports, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to one of the at least two DC power outputs which has been associated with the one of the at least two feedback ports.

A direct current (DC)-DC voltage converter system is provided and comprises: at least two DC power outputs each of which is configured to be coupled through unique electrical conductors, at radio ends of the unique electrical conductors, to a unique measurement sensor and electrically coupled to a unique radio; at least two DC-DC voltage converters each of which is configured to provide DC power to a unique DC power output of the at least two DC power outputs; at least two feedback ports each of which is configured to be communicatively coupled to the unique measurement sensor; and processing circuitry communicatively coupled to each DC-DC voltage converter, and configured to: cause, during a time period, provision of electrical DC power, including a constant DC voltage level, at at least two DC power outputs of the DC-DC voltage converter system, wherein direct current levels drawn during the time period from each of the at least two DC power outputs is different than the direct current levels drawn during the time period from any of other of the at least two DC power outputs; receive measurement data, measured during the time period, (a) at each of the at least two feedback ports, of the DC-DC voltage converter system, from a unique one of measurement sensors and (b) that is derived from a DC voltage level, measured by the unique one of measurement sensors, proximate to radio ends of a unique set of electrical conductors; receive, during the time period, measurements of the direct current levels drawn from each of the at least two DC power outputs of the DC-DC voltage converter system; and using the measurement data measured during the time period received at each of the at least two feedback ports and the direct current levels measured being drawn, during the time period, from each of the at least two DC power outputs, determine an association between each of the at least two DC power outputs and a unique one of the at least two feedback ports, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to one of the at least two DC power outputs which has been associated with the one of the at least two feedback ports.

A direct current (DC)-DC voltage converter system is provided and comprises: at least two DC power outputs each of which is configured to be coupled through unique electrical conductors, at radio ends of the unique electrical conductors, to a unique measurement sensor and electrically coupled to a unique radio; at least two DC-DC voltage converters each of which is configured to provide DC power to a unique DC power output of the at least two DC power outputs; at least two feedback ports each of which is configured to be communicatively coupled to the unique measurement sensor; and processing circuitry communicatively coupled to each DC-DC voltage converter, and configured to: cause provision of electrical DC power, including a constant DC voltage level, during a unique one of sequential time periods at a unique one of the at least two DC power outputs of the DC-DC voltage converter system; receive, during each time period, measurement data (a) at each of the at least two feedback ports, of the DC-DC voltage converter system, from a unique one of measurement sensors and (b) each of which is derived from a DC voltage level measured by the unique one of the measurement sensors electrically connected to and proximate to radio ends of a unique set of electrical conductors; for each time period, identify a feedback port receiving measurement data derived from one of DC voltage levels which exceeds a voltage threshold level; for each time period, determine an association between the feedback port which was identified and one of the at least two DC output ports providing the constant DC voltage level during a unique time period, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to a DC power output, of the at least two DC power outputs, which has been associated with the one of the at least two feedback ports. 39. A method is provided for correctly associating a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system. The method comprises: providing electrical DC power, including a constant DC voltage level, during a unique one of sequential time periods at a unique one of the at least two DC power outputs of the DC-DC voltage converter system; receiving, during each time period, measurement data (a) at each of the at least two feedback ports, of the DC-DC voltage converter system, from a unique one of measurement sensors and (b) each of which is derived from a DC voltage level measured by the unique one of the measurement sensors electrically connected to and proximate to radio ends of a unique set of electrical conductors; for each time period, identifying a feedback port receiving measurement data derived from one of DC voltage levels which exceeds a voltage threshold level; and for each time period, determining an association between the feedback port which was identified and one of the at least two DC output ports providing the constant DC voltage level during a unique time period, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to a DC power output, of the at least two DC power outputs, which has been associated with the one of the at least two feedback ports.

A non-transitory computer readable medium is provided and which stores a program causing at least one processor to execute a process to correctly associate a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system. The process comprises: causing provision of electrical DC power, including a constant DC voltage level, during a unique one of sequential time periods at a unique one of the at least two DC power outputs of the DC-DC voltage converter system; receiving, during each time period, measurement data (a) at each of the at least two feedback ports, of the DC-DC voltage converter system, from a unique one of measurement sensors and (b) each of which is derived from a DC voltage level measured by the unique one of the measurement sensors electrically connected to and proximate to radio ends of a unique set of electrical conductors; for each time period, identifying a feedback port receiving measurement data derived from one of DC voltage levels which exceeds a voltage threshold level; and for each time period, determining an association between the feedback port which was identified and one of the at least two DC output ports providing the constant DC voltage level during a unique time period, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to a DC power output, of the at least two DC power outputs, which has been associated with the one of the at least two feedback ports.

A method is provided for correctly associating a feedback port of a direct current (DC)-DC voltage converter system with a DC power output port of the DC-DC voltage converter system, wherein the DC-DC voltage converter system comprises at least two feedback ports and at least two DC-DC voltage converters each of which is coupled to a unique DC power output. The method comprises: providing a voltage waveform at at least one of at least two DC power outputs of the DC-DC voltage converter system, wherein each DC power output (a) receives a voltage waveform from a unique DC-DC voltage converter of the DC-DC voltage converter system and (b) is configured to be electrically coupled to a DC power input of a unique radio; receiving measurement data (a) at a feedback port, of the DC-DC voltage converter system, from a measurement sensor uniquely communicatively coupled to the feedback port and (b) that is derived from a voltage waveform received by the measurement sensor which is uniquely coupled to a DC power output; determining an association between the DC power output and the feedback port using the measurement data which was received and the voltage waveform which was provided; and at least one of: (a) wherein providing the voltage waveform at at least one of the at least two DC power outputs comprises providing a different voltage waveform, simultaneously, at each of the at least two DC power outputs; and (b) wherein determining the association between the DC power output and the feedback port comprises comparing at least one of: (i) over time, a time varying parameter of the measurement data with a time varying parameter of the voltage waveform and (ii) a characteristic derived, over time, from the time varying parameter of the measurement data with a characteristic derived, over time, from the time varying parameter of the voltage waveform, wherein each of the measurement data and the voltage waveform comprise at least one time varying parameter; wherein the feedback ports are all logical feedback ports or all physical feedback ports.

A non-transitory computer readable medium is provided which stores a program causing at least one processor to execute a process to correctly associating one or more feedback ports of a direct current (DC)-DC voltage converter system with a DC power output port of the DC-DC voltage converter system, wherein the DC-DC voltage converter system comprises at least two feedback ports, and at least two DC-DC voltage converters each of which is coupled to a unique DC power output, the process comprising: causing a voltage waveform to be provided at at least one of at least two DC power outputs of the DC-DC voltage converter system, wherein each DC power output (a) receives a voltage waveform from a unique DC-DC voltage converter of the DC-DC voltage converter system and (b) is configured to be electrically coupled to a DC power input of a unique radio; receiving measurement data received (a) at a feedback port, of the DC-DC voltage converter system, from a measurement sensor uniquely communicatively coupled to the feedback port and (b) that is derived from a voltage waveform received by the measurement sensor which is uniquely coupled to a DC power output; determining an association between the DC power output and the feedback port using the measurement data which was received and the voltage waveform which was caused to be provided; and at least one of: (a) wherein causing the voltage waveform to be provided at at least one of the at least two DC power outputs comprises causing a different voltage waveform to be provided, simultaneously, at each of the at least two DC power outputs; and (b) wherein determining the association between the DC power output and the feedback port comprises comparing at least one of: (i) over time, a time varying parameter of the measurement data with a time varying parameter of the voltage waveform and (ii) a characteristic derived, over time, from the time varying parameter of the measurement data with a characteristic derived, over time, from the time varying parameter of the voltage waveform, wherein each of the measurement data and the voltage waveform comprise at least one time varying parameter; wherein feedback ports are all logical feedback ports or all physical feedback ports.

A direct current (DC)-DC voltage converter system is provided and comprises: at least two DC power outputs each of which is configured to be coupled through unique power conductors to a unique measurement sensor and electrically coupled to a unique radio; at least two DC-DC voltage converters configured to provide DC power to a unique DC power output of the at least two DC power outputs; at least two feedback ports each of which is configured to be communicatively coupled to the unique measurement sensor; and processing circuitry communicatively coupled to each DC-DC voltage converter and each DC-DC voltage converter, and configured to: cause a voltage waveform to be provided at at least one of at least two DC power outputs of the DC-DC voltage converter system, wherein each DC power output (a) receives a voltage waveform from a unique DC-DC voltage converter of the DC-DC voltage converter system and (b) is configured to be electrically coupled to a DC power input of a unique radio: receive measurement data received (a) at a feedback port, of the DC-DC voltage converter system, from a measurement sensor uniquely communicatively coupled to the feedback port and (b) that is derived from a voltage waveform received by the measurement sensor which is uniquely coupled to a DC power output; determine an association between the DC power output and the feedback port using the measurement data which was received and the voltage waveform which was caused to be provided; and at least one of: (a) wherein causing the voltage waveform to be provided at at least one of the at least two DC power outputs comprises causing a different voltage waveform to be provided, simultaneously, at each of the at least two DC power outputs; and (b) wherein determining the association between the DC power output and the feedback port comprises comparing at least one of: (i) over time, a time varying parameter of the measurement data with a time varying parameter of the voltage waveform and (ii) a characteristic derived, over time, from the time varying parameter of the measurement data with a characteristic derived, over time, from the time varying parameter of the voltage waveform, wherein each of the measurement data and the voltage waveform comprise at least one time varying parameter; wherein feedback ports are all logical feedback ports or all physical feedback ports.

### BRIEF DESCRIPTION OF THE DRAWINGS

Understanding that the drawings depict only exemplary embodiments and are not therefore to be considered limiting in scope, the exemplary embodiments will be described with additional specificity and detail through the use of the accompanying drawings, in which:

FIG. 1A illustrates a block diagram of one embodiment of a DC-DC voltage converter system;

FIG. 1B illustrates a block diagram of another embodiment of a DC-DC voltage converter system;

FIG. 1C illustrates a block diagram of one embodiment of a DC voltage converter;

FIG. 2 illustrates a flow diagram of one embodiment of a method for correctly associating a feedback port of a DC-DC voltage converter system and a DC power output port of the DC-DC voltage converter system;

FIGS. 3A-D illustrate diagrams of exemplary direct current levels which were being drawn from different DC power outputs during the time period;

FIGS. 3E-H illustrate diagrams of exemplary voltage levels of measurement data received at different feedback ports during the time period;

FIGS. 4A-D illustrate diagrams of a linear regression of exemplary direct current levels which were being drawn from different four DC power outputs during the time period with respect to exemplary DC voltage levels received at a first logical or physical feedback port and measured during the same time period;

FIGS. 4E-H illustrate diagrams of a linear regression of exemplary direct current levels which were being drawn from different four DC power outputs during the time period with respect to exemplary DC voltage levels received at a second logical or physical feedback port and measured during the same time period;

FIGS. 4I-L illustrate diagrams of a linear regression of exemplary direct current levels which were being drawn from different four DC power outputs during the time period with respect to exemplary DC voltage levels received at a third logical or physical feedback port and measured during the same time period;

FIGS. 4M-P illustrate diagrams of a linear regression of exemplary direct current levels which were being drawn from different four DC power outputs during the time period with respect to exemplary DC voltage levels received at a fourth logical or physical feedback port and measured during the same time period; and

FIG. 5 illustrates a flow diagram of one embodiment of a method 550 for determining a resistance of at least one set of electrical conductors each of which whose first ends are electrically coupled to a unique power output of a DC-DC voltage converter system and whose radio ends are electrically coupled to a DC power input of a unique radio.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of specific illustrative embodiments in which the invention may be practiced. These embodiments are described in sufficient detail to enable those skilled in the art to practice the invention, and it is to be understood that other embodiments may be utilized and that logical, mechanical, and electrical changes may be made without departing from the scope of the present invention. The following detailed description is, therefore, not to be taken in a limiting sense.

Techniques are provided for correctly associating (or mapping) a feedback port, e.g., a logical feedback port, of a DC-DC voltage converter system (or a measurement sensor communicatively coupled thereto) and a DC power output port of the DC-DC voltage converter system. Mapping ensures that a DC voltage level measured at radio ends of electrical conductors (feedback approach) or a determined resistance of the electrical conductors (resistance determination approach) is used to regulate a DC voltage level of the DC power output electrically coupled to the electrical conductors. Alternatively, such association or map can be avoided by determining a resistance of electrical conductors electrically coupled to each DC power output of a DC-DC voltage converter system.

Embodiments of the invention may be used for a macro cell, e.g., of a cellular base station, e.g., where one or more radios and measurement sensors are mounted on a tower. In other embodiments of the invention may be used for a metro cell, e.g., comprising small cell(s) and/or distributed antenna system(s), which is configured to augment capacity and/or coverage of macro cell(s).

Optionally, measurement data (measured during the same time period) may be sent serially by more than one measurement sensor to a single physical feedback port of a DC-DC voltage converter system. The DC-DC voltage converter system may comprise logical feedback ports each of which provides measurement data from a unique measurement sensor.

Thus, logical feedback port means a unique measurement data, e.g., from a unique measurement sensor, (or unique electrical conductors configured to provide such set of unique data) provided by the physical feedback port.¹ Optionally, a logical feedback port is configured to receive data and to communicate such data to an application program. Optionally, such application program may be configured to perform, at least in part, method 220 described elsewhere herein. Each logical feedback port is communicatively coupled to a unique measurement sensor. ¹Optionally, measured voltage data from one or more (or two or more) voltage sensors is transmitted sequentially in time in a packet of measured voltage data through a same set of electrical conductors to the DC-DC voltage converter system. Measured voltage data from each voltage sensor is sent in a unique time slot of the packet. Thus, each time slot, of a packet of measured voltage data from the one or more (or the two or more) voltage sensors, may be considered a logical feedback port of the DC-DC voltage converter system. Optionally, a data buffer or a deserializer may be used to convert the sequential data (where a data set is sequentially transmitted at different times over the same set of electrical conductors) into parallel data (where the same data is sent in parallel at the same time over different sets of electrical conductors).

By having a correct association, measurement data from a measurement sensor coupled to a DC-DC voltage converter are fed back to a processing system and used to control a DC voltage level provided by the DC-DC voltage converter. The processing system is further configured to adjust a DC voltage provided by the DC-DC voltage converter so that a parameter measured by the measurement sensor equals a target DC electrical parameter, e.g., a DC voltage level or a direct current level. This technique can be utilized to associate each feedback port, e.g., each logical feedback port) of the DC-DC voltage converter system (or a measurement sensor communicatively coupled thereto) with a unique DC power output, of the DC-DC voltage converter system, to provide a DC voltage level to a DC power input of a radio which is within a DC voltage power input range of the radio in which the voltage level must be maintained for the radio to operate properly. The DC power input is coupled to a measurement sensor communicatively coupled to the unique power output and which provides measurement data to a feedback port, e.g., each logical feedback port. Such measurement data is received by the processing system and used by the processing system to control the DC voltage level provided by a DC-DC voltage converter electrically coupled to the unique DC power output. The correct association avoids the aforementioned problems.

Techniques are also provided for identifying an error in an initial association(s) between (a) a feedback port, e.g., a logical feedback port, (or a measurement sensor communicatively coupled thereto) and (b) a DC power output port of a DC-DC voltage converter (and thus the DC-DC voltage converter). Optionally, the initial association(s) are provided by an installer of the DC-DC voltage converter system and/or a network operator which operates the base station and thus the DC-DC voltage converter system. Optionally, additional techniques are provided for correcting any such error(s); as a result, a feedback signal from a measurement sensor is used to control a DC voltage provided by a DC-DC voltage converter electrically coupled to a radio whose DC power input is coupled to the measurement sensor. The feedback signal is conveyed by a feedback connection between the measurement sensor and the processing system coupled to the DC-DC voltage converter. Optionally, additional techniques may provide notice to an installer and/or network operator of such erroneous association(s) and/or corrections of such erroneous association(s).

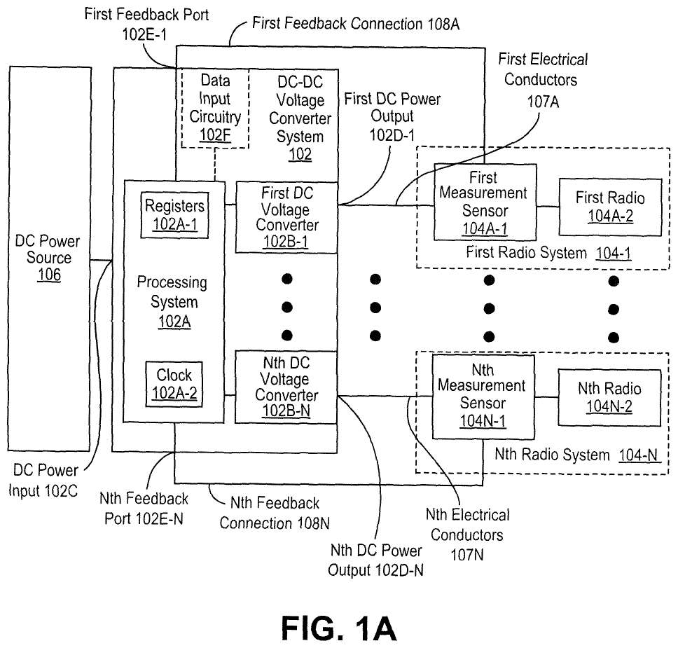

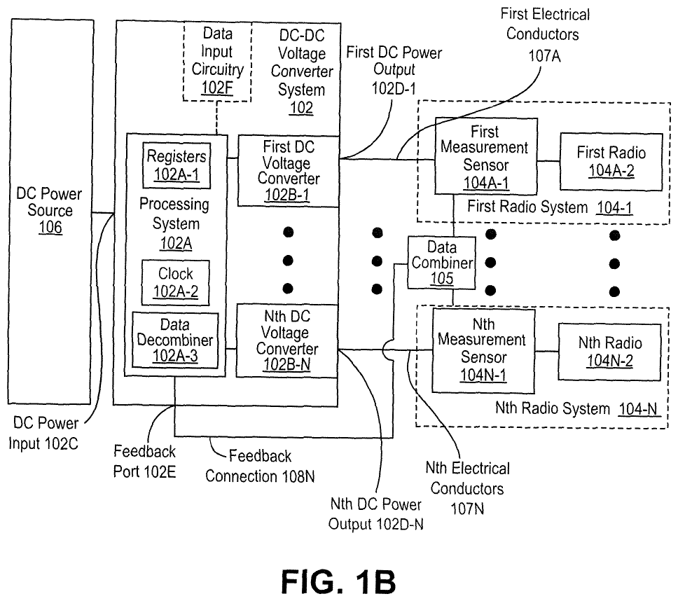

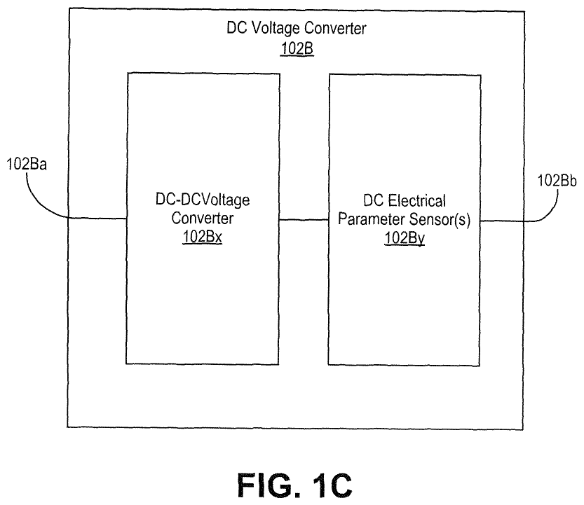

FIG. 1A illustrates a block diagram of one embodiment of a DC-DC voltage converter system 102. The DC-DC voltage converter system 102 includes a processing system (or processing circuitry) 102A, N DC-DC voltage converters 102B-1, 102B-N, a DC power input 102C, N DC power outputs 102D-1, 102D-N, and N feedback ports 102E-1, 102E-N. N is an integer greater than one. Each feedback port illustrated in FIG. 1A is a physical feedback port. Each of the N DC power outputs 102D-1, 102D-N is a DC power output of a unique DC-DC voltage converter, and thus of the DC-DC voltage converter system 102. Each DC-DC voltage converter 102B-1, 102B-N is configured to establish the DC voltage at a corresponding DC power output 102D-1, 102D-N. Optionally, each DC-DC voltage converter 102B-1, 102B-N is a boost converter or a buck-boost converter.

The DC power input 102C is configured to be electrically coupled to a DC power source 106. The DC power source 106 is configured to provide DC electrical power to the DC-DC voltage converter system 102, through the DC power input 102C. The DC electrical power, provided by the DC power source 106, has a DC power source voltage level, e.g., −54 volts DC (VDC) which is also provided to the DC power input 102C of the DC-DC voltage converter system 102. Optionally, the DC power source voltage level is provided to an input of each DC-DC voltage converter 102B-1, 102B-N of the DC-DC voltage converter system 102. Optionally, the DC power source 106 includes an alternating current (AC) to direct current (DC) (AC/DC) power supply, at least one battery, at least one solar cell, and/or any other type of DC power source.

Each DC-DC voltage converter 102B-1, 102B-N and each feedback port 102E-1, 102E-N are electrically coupled to the processing system 102A. Each ith DC-DC voltage converter 102B-1, 102B-N is electrically connected to an ith DC power output. Each jth DC power output is configured to be coupled through jth electrical conductors to a jth measurement sensor and a jth radio. Optionally, each coupled pair of measurement sensor 104A-1, 104A-N and radio 104A-2, 104A-N may be part of a radio system, e.g., a first radio system 104-1 and an Nth radio system 104-N. Optionally, a radio system includes an enclosure that includes a measurement sensor and a radio.

Each measurement sensor is configured to measure a DC electrical parameter value, e.g., a DC voltage level or a direct current level; thus, optionally, a measurement sensor may be a voltage sensor or a current sensor. The measurement sensor may also be referred herein as measurement circuitry. For pedagogical reasons, each measurement sensor 104A-1, 104N-1 is illustrated in FIGS. 1A and 1B as being serially electrically coupled between electrical conductors 107A, 107N and a radio 104A-2, 104N-2; however, alternatively, if the measurement sensor is a magnetically coupled current sensor, such as a Hall effect sensor, the measurement sensor is magnetically coupled, e.g., to the electrical conductors 107A, 107N and is not serially electrically coupled as illustrated.

Each feedback port 102E-1, 102E-N is configured to be communicatively coupled through a feedback connection (or a feedback communications link) 108A, 108N to a measurement sensor 104A-1, 104A-N. Each feedback connection 108A, 108N may be a wired or a wireless connection configured to convey analog or digital data. Optionally, the wired connection may be a parallel or serial wired connection using a wired communications protocol, e.g., compliant with an RS-485 standard. For purposes of clarity, the RS-485 standard is used throughout as an example of a serial data interface; other serial data interface protocols may be used in lieu of the RS-485 standard. Optionally, the wireless connection may use a wireless communications protocol, e.g., used for local area networks (for example, an IEEE compliant 802.11 protocol) or personal area networks (for example, a Bluetooth protocol). Thus, each measurement sensor includes a transmitter (or a transceiver) corresponding to the communications protocol employed; each feedback port includes a receiver (or a transceiver) configured for the communications protocol employed.

The DC-DC voltage converter system 102 optionally includes data input circuitry 102F electrically coupled to the processing system 102A. Optionally, the data input circuitry 102F includes an input/output interface (e.g., a touch screen) and/or a receiver (or transceiver) (e.g., configured for a wide area network, a local area network, and/or a personal area network) configured to receive externally provided data from an external computing system, e.g., a mobile telephone, a tablet, or any remote computing system. The data input circuitry 102F is optionally configured to receive, e.g., from the installer and/or the network operator (as described elsewhere herein, externally provided initial association(s) of a feedback port and a DC power output port of a DC-DC voltage converter (and thus the DC-DC voltage converter).

The processing system 102A may be any type of computational system, e.g., a state machine, neural network, and/or another type of computational system. In one embodiment, the processing system 102A comprises a processor circuitry electrically coupled to memory circuitry. The processing system 102A includes registers 102A-1, e.g., of the memory circuitry. Optionally, the processing system 102A includes a clock 102A-2 configured to keep time. The optionally received initial association(s) of (a) a feedback port and (b) a DC power output port of a DC-DC voltage converter (and thus the DC-DC voltage converter) is configured to be stored as such registers 102A-1.

The registers 102A-1 is also optionally configured to store a final association(s) of (a) a feedback port and (b) a DC power output port of a DC-DC voltage converter (and thus the DC-DC voltage converter). The registers 102A-1 is also optionally configured to store data representative of a waveform provided at each DC power output from a corresponding DC-DC voltage converter, and optionally a start and stop time of each waveform. The registers 102A-1 is also optionally configured to store data representative of waveforms received at each feedback port. The registers 102A-1 is further optionally configured to store the target DC electrical parameter described elsewhere herein.

FIG. 1B illustrates a block diagram of another embodiment of a DC-DC voltage converter system 102. In this other embodiment a single feedback connection 108 communicatively couples measurement data from each measurement sensor 104A-1, 104N-1 to a single, i.e., physical, feedback port 102E. The single feedback connection 108 may be a wired or wireless connection configured to convey analog or digital data. Optionally, measurement data, measured substantially at the same time by each measurement sensor 104A-1, 104N-1, may be conveyed in a serial and/or a parallel data interface format through the single feedback connection 108. Optionally, when data is conveyed serially through the single feedback connection 108, an IEEE RS-485 protocol is used.

The DC-DC voltage converter system 102 of FIG. 1B includes a data combiner (data combiner circuit) 105 and data decombiner (or data decombiner circuit) 102A-3. The data combiner 105 is configured to be located remote from the DC-DC voltage converter system 102 and proximate to, e.g., at, the measurement sensors 104A-1, 104N-1. The data combiner 105 combines, serially and/or in parallel, measurement data measured by each measurement sensor 104A-1, 104N-1 at substantially the same time, and transmits the measurement data, measured at substantially the same time and combined serially and/or in parallel, through the feedback connection 108N. Optionally, a data combiner 105 need not be used; data outputs of each measurement sensor may be serially daisy chained one to another.

For pedagogical purposes, the data decombiner 102A-3 is illustrated as part of the processing system 102A; however, the data decombiner 102A-3 may be located outside of the processing system 102A. The data decombiner 102A-3 is configured to extract measurement data measured by each measurement sensor 104A-1, 104N-1 at substantially the same time and combined serially or in parallel. Although the DC-DC voltage converter system 102 comprises a single physical feedback port 102E, the output of the data decombiner 102A-3 may be considered to comprise a set of logical feedback ports equivalent to the physical feedback ports 102E-1, 102E-N illustrated in FIG. 1A. Measured (or measurement) data received from a unique measurement sensor and provided by the output of the data decombiner 102A-3 corresponds to a unique logical feedback port of the set of logical feedback ports. Each logical feedback port corresponds to a unique relative time or an electrical output (e.g., a set of electrical conductors) of the data decombiner 102A-3. Such relative times or electrical outputs may be designated by a system designer and/or system user. For example, the first measurement data (for a measurement period) of data provided serially or in parallel may be associated with a first time slot or a first electrical output, the second measurement data (for the measurement period) may be associated respectively with a second time slot or a second electrical output, etc.; however, other arbitrary combinations may be utilized. Thus, each logical feedback port corresponds to a unique measurement sensor and provides data from such unique measurement sensor.

FIG. 1C illustrates a block diagram of one embodiment of a DC voltage converter 102B. Optionally, the illustrated DC voltage converter may be used to implement the DC voltage converters 102B-1, 102B-N illustrated in FIGS. 1A and 1B. The DC voltage converter 102B includes an input 102Ba, a DC-DC voltage converter 102Bx, at least one DC electrical parameter sensor(s) 102By, and an output 102Bb. The input 102Ba of the DC voltage converter 102B is electrically coupled to an input of the DC-DC voltage converter 102Bx. Optionally, the DC-DC voltage converter is a boost voltage converter. An output of the DC-DC voltage converter 102Bx is coupled, e.g., magnetically or electrically, to at least one DC electrical parameter sensor (DC electrical parameter sensor(s)) 102By. Optionally, the DC electrical parameter sensor(s) 102By includes a current sensor and/or a voltage sensor. The output 102Bb of the DC voltage converter 102B is electrically coupled to the output of the DC-DC voltage converter 102Bx.

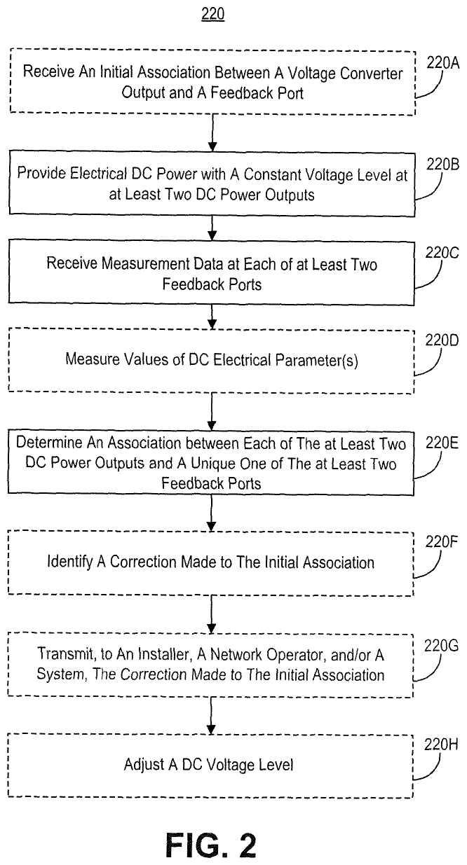

FIG. 2 illustrates a flow diagram of one embodiment of a method 220 for correctly associating a physical or logical feedback port of a DC-DC voltage converter system and a DC power output port of the DC-DC voltage converter system. The DC-DC voltage converter system comprises at least two logical feedback ports and at least two DC-DC voltage converters each of which is coupled to a unique DC power output. Optionally, each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system.

The methods illustrated herein may be implemented with, e.g., the processing system 102A of, the DC-DC voltage converter system 102 illustrated and described with respect to FIGS. 1A and 1B but may be implemented with other systems as well. For pedagogical purposes, implementation of the methods is described with respect to FIGS. 1A and 1B. The feedback port(s) described with respect to this method may be physical feedback port(s) or logical feedback port(s).

The blocks of the flow diagrams have been arranged in a generally sequential manner for ease of explanation; however, it is to be understood that this arrangement is merely exemplary, and it should be recognized that the processing associated with the methods described herein (and the blocks shown in the Figures) may occur in a different order (for example, where at least some of the processing associated with the blocks is performed in parallel and/or in an event-driven manner).

In optional block 220A, an initial association of (a) a feedback port (or a measurement sensor communicatively coupled thereto) and (b) a DC power output port of a DC-DC voltage converter (and thus the DC-DC voltage converter) is received, e.g., by the processing system 102A. Optionally, the initial association is received from, e.g., an installer who installed the DC-DC voltage converter system 102 and/or a network operator which operates a base station including a radio powered by the DC-DC voltage converter system 102. Optionally, the initial association is received through data input circuitry 102F by the processing system 102A and stored as registers 102A-1.

In block 220B, a constant DC voltage level, at at least two DC power outputs of the DC-DC voltage converter system, is provided; the constant DC voltage level may be provided sequentially or in parallel. Optionally, the constant DC voltage level is equal to or greater than a minimum DC voltage level rating of a radio (which the radio requires to operate) plus a worst case voltage drop in the electrical conductors (due to current flow therein) electrically connecting a DC power output to a DC power input of the radio. Optionally, the constant DC voltage level is provided from the DC power source 106 directly to one or more DC power outputs and not from a voltage converter whose output is electrically connected to each of the one or more DC power outputs; alternatively, the constant DC voltage level is provided by each DC voltage converter whose output is electrically connected to one of the one or more DC power outputs. Optionally, the constant DC voltage level is a voltage level provided by the DC power source 106, e.g., at the DC power input 102C, or a voltage level that is different, e.g., larger, than the voltage level provided by the DC power source 106.

Optionally, the constant DC voltage level is provided to the at least two DC power outputs 102D-1, 102D-N in parallel, i.e., at substantially the same time for each DC power output. Optionally, the constant DC voltage level is provided to the at least two DC power outputs 102D-1, 102D-N sequentially. When provided sequentially, the constant DC voltage level means a fixed DC voltage level provided at only one DC output port during a unique time period and which is different than the DC voltage level(s) provided at other DC output ports during the unique time period; thus, for example, the other DC output ports may provide, during the unique time period, DC voltage level(s), constant or non-constant, that are different (e.g., in voltage magnitude and/or by being time varying) than the constant DC voltage level provided at the only one DC output port. The constant DC voltage will be sufficiently different from the different DC voltage level(s) so that the other constant DC voltage can be discriminated from the different DC voltage level(s), and thus detected.

Providing the constant DC voltage level in parallel to the at least two DC power outputs 102D-1, 102D-n means providing the constant DC voltage level, at each DC power output, at a same time period. Providing the constant DC voltage level sequentially to the at least two DC power outputs 102D-1, 102D-n means providing the constant DC voltage level, at each DC power output, at a different time period. Optionally, the processing system 102A is configured to cause the DC-DC voltage converter to provide the constant DC voltage level, e.g., sequentially or in parallel, at an output of two or more DC voltage converters 102B-1, 102B-N. Optionally, each power output is electrically coupled, e.g., through unique electrical conductors to a DC power input of a unique radio and a unique measurement sensor each of which is proximate to, e.g., at, the radio ends of the electrical conductors.

In block 220C, measurement data is received at each logical or physical feedback port from a unique measurement sensor and that is derived from a DC voltage level, measured by the unique measurement sensor, at radio ends of the unique electrical conductors. Optionally, measurement data is received sequentially (i.e., at different time periods) or in parallel (i.e., at the same time period) at each logical or physical feedback port.

In one embodiment, a constant DC voltage level is sequentially (i.e., at different time periods) provided to each DC power output 102D-1, 102D-N. Optionally, if the constant DC voltage level is sequentially (i.e., at different time periods) provided to each DC power output 102D-1, 102D-N, then each radio 104A-2, 104N-2 need not be electrically powered on or disconnected from electrical power, e.g., not even installed. The electrical conductors 107A, 107N need only be electrically coupled to corresponding measurement sensors 104A-1, 104N-1. In such a case, there is no current drawn through the electrical conductors electrically configured to connect the radio to a DC power output of the DC-DC voltage converter system 102. As a result, the DC voltage across the radio ends² of the electrical conductors equals the constant DC voltage provided at the DC power output to the first ends of the electrical conductors. Thus, such constant DC voltage will be measured or sensed, during the unique time period, by one measurement sensor coupled to the radio ends of the electrical conductors (opposite the first ends of the electrical conductors); during the unique time period, the other measurement sensors will sense different DC voltage level(s) as described above. ² The radio ends of each electrical conductors are remotely located from the DC-DC voltage converter system 102, and proximate, e.g., at, to a radio system, e.g., a radio, to which they are electrically coupled.

During sequential provision of the constant DC voltage level, if the radio is electrically connected, through electrical conductors, to a power output of the DC-DC voltage converter system 102 and the radio is powered on, then the radio may draw current from the DC power output through the electrical conductors. Due to a voltage drop across the electrical conductors, the DC voltage across the radio ends of the electrical conductors may not equal the constant DC voltage provided at the DC power output to the first ends of the electrical conductors. Due to such voltage drop, another constant DC voltage may be measured or sensed, during each time period, by one measurement sensor coupled to the radio ends of the electrical conductors as described above; during each such time period, the other measurement sensors will sense different DC voltage level(s) as described above. The other constant DC voltage will be sufficiently different from the different DC voltage level(s) so that the other constant DC voltage can be discriminated from the different DC voltage level(s), and thus detected.

Regardless of whether or not the radio is electrically connected to electrical power or powered on, because the constant DC voltage is provided sequentially (i.e., at different time periods) at each DC power output 102D-1, 102D-N, then only one measurement sensor, e.g., a voltage sensor, will provide a a voltage measurement which is different than, and can be distinguished from, the other voltage measurements provided by other measurement sensors. Optionally, for sequential provision of the constant DC voltage level, the voltage measurement which is different can be distinguished from the other voltage measurements because the magnitude of the measured voltage, or an average thereof, exceeds a voltage threshold voltage level. Such voltage measurement data is provided through electrical conductors or a wireless connection coupling such only one measurement sensor to a unique (physical or logical) port of the DC-DC voltage converter system 102. Optionally, when the constant DC voltage level is provided sequentially, the DC-DC voltage converter system 102, e.g., the processing system 102A, is configured to store, e.g., in a table, the DC output port providing the constant DC voltage level and a time or a time period when the DC output port provides the constant DC voltage level.

Optionally, for sequential provision of the constant DC voltage level, blocks 220B, 220C, 220E, and optionally 220D may be performed sequentially. That is, the provision of electrical DC power, receipt of measurement data, and association determination may be repeated for each DC power output which is provided the constant DC voltage level. Thus, only one pair of a DC output port and a logical or physical feedback port are associated at a time. Optionally, after being associated, a DC output port and a logical or physical feedback port no longer, the direct current levels drawn from the logical or physical feedback port need no longer be analyzed when determine later associations of DC output port(s) and logical or physical feedback port(s).

Optionally, if the constant DC voltage level is provided in parallel (i.e., at a same time period) to each DC power output 102D-1, 102D-N, then measurement data, e.g., a voltage level, at each measurement sensor and during such same time period, is provided to a logical or physical feedback port electrically connected to the measurement sensor. Parallel provision of the constant DC voltage may also be referred to herein as simultaneous provision of the constant DC voltage. Optionally, the DC-DC voltage converter system 102, e.g., the processing system 102A, is configured to store such measurement data received at each logical or physical feedback port, e.g., during the same time period.

In optional block 220D, at least one DC electrical parameter about DC power provided at each DC power output is measured. Optionally, when the constant DC voltage is provided sequentially (i.e., at different time periods) at each DC power output, the DC electrical parameter sensor(s) 102By of each DC voltage converter 102B includes a voltage sensor configured to measure a DC voltage level at the DC power output of the DC voltage converter 102B; the DC-DC voltage converter system 102, e.g., the processing system 102A, is configured to store, e.g., in a table, (a) a time or time period when a non-zero DC voltage is measured at an output, of a DC voltage converter, electrically connected to a unique DC power output, and (b) the unique DC power output. Optionally, when the constant DC voltage is provided in parallel (i.e., at a same time period) at each DC power output, the DC electrical parameter sensor(s) 102By of each DC voltage converter 102B includes a current sensor configured to measure a direct current level drawn from the DC power output of the DC voltage converter 102B. Direct current levels (drawn from an output of each DC voltage converter electrically connected to a unique DC power output) are measured during the time period when the constant DC voltage is provided in parallel; optionally, each such direct current levels and the unique DC power output from which they are drawn are stored, e.g., in a table.

Optionally, when method 220 is performed for parallel provision of the DC constant voltage, a measure of variation of at least one of the at least one DC electrical parameter (e.g., direct current) measured during the time period is determined. For pedagogical purposes, the at least one of the at least one DC electrical parameter shall be described as direct current. Such a measure of variation, for example may be a statistical parameter, e.g., a standard deviation for a set of direct current levels drawn from a DC power output during the time period. Alternatively, the measure of variation can be a magnitude of a difference between a largest magnitude of a direct current level and a mean direct current level of the set. This may be performed for each set of direct current levels drawn from each of the at least two DC power outputs during the time period. Then, the measure of variation may be compared to a variation threshold level. If the measure of variation exceeds the variation threshold level, the remaining blocks of method 220 may be performed. If the measure of variation does not exceed the variation threshold level, then the performance of method 220 is stopped and not concluded.

Using the measurement data received at each of the at least two logical feedback ports and at least one value of a DC electrical parameter of electrical power provided at a unique DC power output of the at least two DC power outputs, in block 220E, an association (e.g., a final association), between each of the at least two DC power outputs and a unique one of the at least one logical or physical feedback port, is determined. Optionally, when sequential provision of the constant DC voltage is used, using received measurement data unique time periods, such association can be made by identifying pairs of a DC power output providing the constant DC voltage and a logical or physical feedback port receiving measurement data including voltage levels whose magnitudes, or whose average of such magnitudes, exceeds a voltage threshold level.

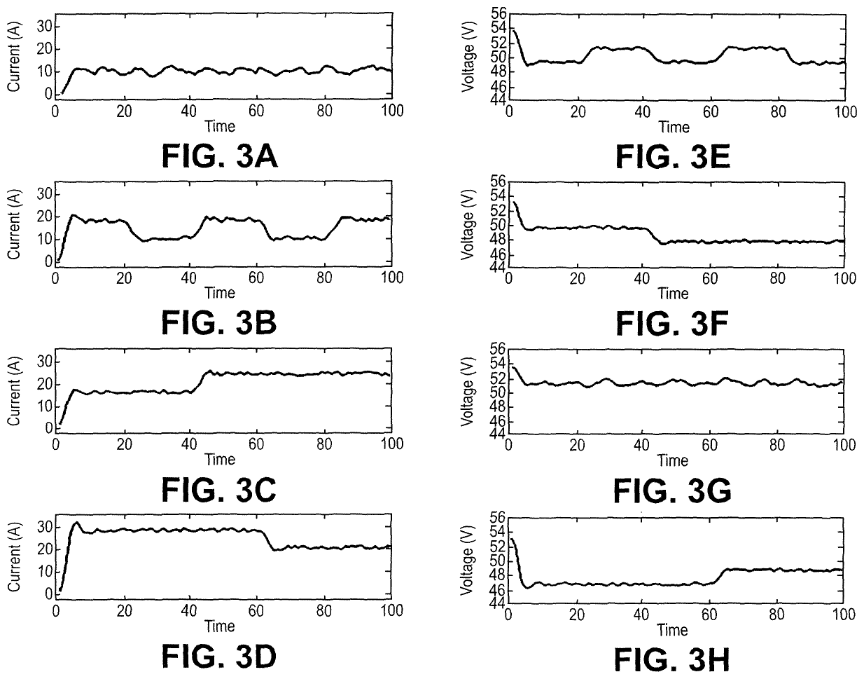

Optionally, when parallel (or simultaneous) provision of the constant DC voltage is used, such association can be made by performing a correlation of each possible combination of (a) direct current levels which were measured being drawn from each DC power output during a time period and (b) measurement data received, measured during the time period, at each logical or physical feedback port. Optionally such direct current levels and measurement data are stored, e.g., in memory circuitry of the processing system. FIGS. 3A-D illustrate diagrams of exemplary direct current levels which were being drawn from different DC power outputs during the time period. FIGS. 3E-H illustrate diagrams of exemplary voltage levels of measurement data received at different feedback ports during the time period. For pedagogical purposes, the measurement\d data of FIGS. 3A-H are illustrated as voltage levels, but need not be so.

During the time period when the constant DC voltage is provided in parallel (or simultaneously), levels of the direct current drawn from each DC power output by a radio should be different; as a result, due to a voltage drop in each electrical conductor (electrically coupling a DC power output to a radio), measurement data derived from a voltage measured at radio ends of each electrical conductors then be different. The direct current level drawn from a DC power output during the time period will be correlated with measurement data derived from a voltage level measured by a measurement sensor coupled to radio ends of an electrical conductor electrically connected to the DC power output. This is illustrated in FIGS. 3A-H.

Variations, during the time period, in direct current levels may occur during normal operation of each radio electrically coupled to and powered from the at least two DC output ports. Such variations in direct currents may occur, e.g., due to a mode (e.g., sleep or active) changes and/or changes in amount data transmitted by each radio; the higher an amount of data transmitted by a radio, the greater amount of direct current drawn by the radio from a corresponding DC power output. Alternatively, the direct current may be varied by sequentially powering on, e.g., initializing, each radio during the time period; as a result each radio will commence drawing higher levels of direct current at different times during the time period. Each radio may be powered on, for example, by (a) providing the constant DC voltage at each of the at least two DC power outputs during the time period and by turning on each radio sequentially with a baseband unit or manually or (b) having all radios turned on and providing the constant DC voltage at each of the at least two DC power outputs sequentially.

A correlation, of each possible combination of (a) direct current levels measured being drawn from each of the at least two DC power outputs and (b) measurement data received at each of the at least two logical feedback ports, is determined. The at least two DC power outputs (or output ports) at which electrical DC power, including a constant voltage level, is provided equals N power outputs. N is an integer value. N pairs, of each such direct current levels and the measurement data having largest correlations of all of the correlations determined, are determined. For each of the N pairs, one of the at least two DC power outputs associated with the direct current level of a pair and one of the at least two logical feedback ports associated with the measurement data of the pair, are identified. Optionally, such correlation may include performing preprocessing such as inversion (i.e., change of sign) of measurement data or measured values of DC electrical parameter(s), normalization of measurement data, or measured values of DC electrical parameter(s), and/or other processes; for example preprocessing of correlation may include determining a mean of measurement data or measured values of DC electrical parameter(s), subtracting the mean from respectively the measurement data or the measured values of the DC electrical parameter(s), inverting respectively the measurement data or the measured values of the DC electrical parameter(s), and adding the mean to respectively the measurement data or the measured values of the DC electrical parameter(s).

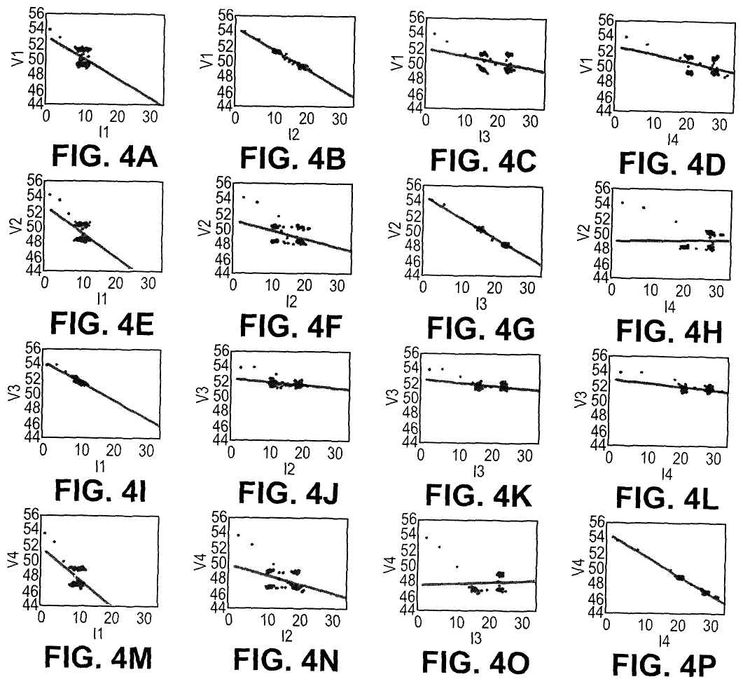

Alternatively and optionally, when parallel (or simultaneous) provision of the constant DC voltage is used, such association can be made by performing a linear regression of each possible combination of (a) direct current levels measured being drawn from each DC power output during a time period and (b) measurement data (measured during the time period) received at each logical or physical feedback port. Optionally such direct current levels and measurement data are stored, e.g., in memory circuitry of the processing system. FIGS. 4A-D illustrate diagrams of a linear regression of exemplary direct current levels which were being drawn from different four DC power outputs during the time period with respect to exemplary DC voltage levels received at a first logical or physical feedback port and measured during the same time period. FIGS. 4E-H illustrate diagrams of a linear regression of exemplary direct current levels which were being drawn from different four DC power outputs during the time period with respect to exemplary DC voltage levels received at a second logical or physical feedback port and measured during the same time period. FIGS. 4I-L illustrate diagrams of a linear regression of exemplary direct current levels which were being drawn from different four DC power outputs during the time period with respect to exemplary DC voltage levels received at a third logical or physical feedback port and measured during the same time period. FIGS. 4M-P illustrate diagrams of a linear regression of exemplary direct current levels which were being drawn from different four DC power outputs during the time period with respect to exemplary DC voltage levels received at a fourth logical or physical feedback port and measured during the same time period.

FIGS. 4A, 4E, 4I, and 4M illustrate diagrams of a linear regression of exemplary DC voltage levels, received at four different logical or physical feedback ports and measured during the time period, with respect to exemplary direct current levels drawn from a first DC power output during the time period. FIGS. 4B, 4F, 4J, and 4N illustrate diagrams of a linear regression of exemplary DC voltage levels, received at four different logical or physical feedback port and measured during the time period, with respect to exemplary direct current levels drawn from a second DC power output during the time period. FIGS. 4C, 4G, 4K, and 40 illustrate diagrams of a linear regression of exemplary DC voltage levels, received at four different logical or physical feedback port and measured during the time period, with respect to exemplary direct current levels drawn from a third DC power output during the time period. FIGS. 4D, 4H, 4L, and 4P illustrate diagrams of a linear regression of exemplary DC voltage levels, received at four different logical or physical feedback port and measured during the time period, with respect to exemplary direct current levels drawn from a fourth DC power output during the time period.

Thus, linear regression may be performed for:
(a) for each feedback port, DC voltage levels received at a feedback port and derived from measurements during the time period with respect to measurements of direct current levels drawn from each DC power output during the time period;
(b) for each DC power output, direct current levels drawn from a DC power output during the time period with respect to DC voltage levels received at each feedback port and derived from measurements during the time period; or
(c) every combination of (x) DC voltage level received at a feedback port and derived from measurements during the time period and (y) measurements of direct current levels drawn from a DC power output during the time period.

A linear regression of each possible combination of (p) direct current levels measured being drawn from each of the at least two DC power outputs and (q) measurement data received at each of the at least two logical feedback ports, is performed, and a standard deviation, of the direct current levels and measurement data used for the linear regression with respect to a line determined by the linear regression, is determined. The at least two DC power outputs at which electrical DC power, including a constant voltage level, is provided equals M power outputs. M is an integer value. M pairs, of each such direct current levels and the measurement data having smallest standard deviations of all of the standard deviations determined, are determined. For each of the M pairs, one, of the at least two DC power outputs associated with the direct current level of a pair and a logical feedback port associated with the measurement data of the pair, is identified.

In block 220F, corrections made to the initial associations to arrive at the final association(s) are identified. The corrections are determined by comparing the final association(s) with the initial association(s) and identifying differences between the final association(s) and the initial association(s). In optional block 220G, the corrections are transmitted to an installer, a network operator, and/or a system which tracks such corrections to notify them of the corrections.

In optional block 220H, using the association, e.g., the final association, and other measurement data, received at the feedback port, from the measurement sensor, is used to adjust a DC voltage level provided by a DC-DC voltage converter to the DC power output. Optionally, the DC voltage level is within a DC voltage input range, of the radio only in which the radio operates properly. Optionally, such DC voltage level provided at the DC power input of the radio exceeds a nominal DC voltage level, e.g., −48V, which the radio manufacturer specifies should be provided to the DC power input of the radio, DC power loss in the electrical conductors is diminished.

The aforementioned techniques allow each physical or logical feedback port to be associated with (or mapped to) a unique DC power output coupled through a unique measurement sensor to a physical or logical feedback port. Alternative techniques are provided which determine a resistance of the electrical conductors coupled to the DC power output ports so that such association (or mapping) need not be performed and can be avoided. Embodiments for doing so are subsequently described.

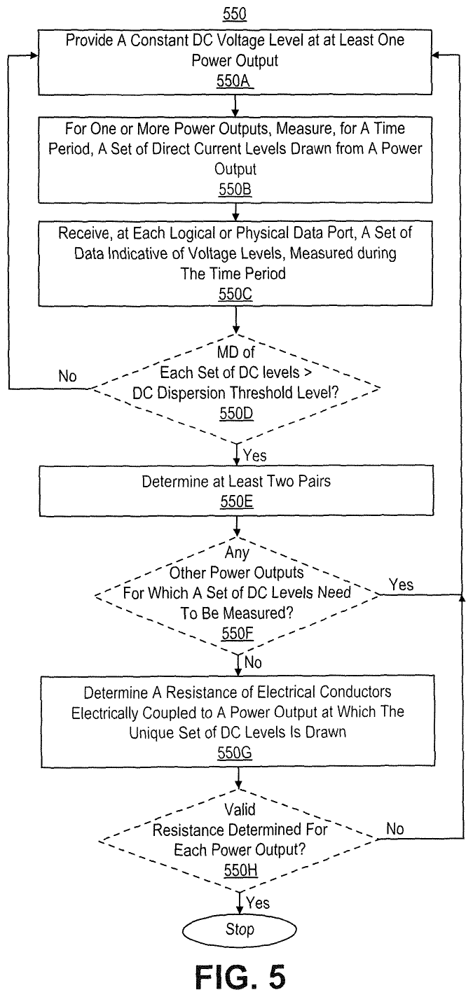

FIG. 5 illustrates a flow diagram of one embodiment of a method 550 for determining a resistance of at least one set of electrical conductors each of which whose first ends are electrically coupled to a unique power output of a DC-DC voltage converter system and whose radio ends are electrically coupled to a DC power input of a unique radio. The methods illustrated herein may be implemented with, e.g., the processing system 102A of, the DC-DC voltage converter system 102 illustrated and described with respect to FIGS. 1A and 1B but may be implemented with other systems as well. For pedagogical purposes, implementation of the methods is described with respect to FIGS. 1A and 1B. The feedback port(s) described with respect to this method may be physical feedback port(s) or logical feedback port(s).

Portions of method 550 may be performed once or repeated two or more times to determine the resistance of the electrical conductors coupled to each power output of the DC-DC voltage converter system. Optionally, the resistance for one or more (but not greater than a total number of the power outputs of the DC-DC voltage converter system) may be determined during each performance of method 550.

The blocks of the flow diagrams have been arranged in a generally sequential manner for ease of explanation; however, it is to be understood that this arrangement is merely exemplary, and it should be recognized that the processing associated with the methods described herein (and the blocks shown in the Figures) may occur in a different order (for example, where at least some of the processing associated with the blocks is performed in parallel and/or in an event-driven manner).

In block 550A, a constant DC voltage level is provided at each of at least one power output (e.g., at least two power outputs) of the DC-DC voltage converter system. Each of the at least one power outputs of the DC-DC voltage converter system is configured, when providing the constant DC voltage level, to deliver a DC electrical power (at a DC power input of each radio electrically coupled by electrical conductors to one of the at least one power outputs) whose parameters are sufficient to enable operation of the radio. For example, such constant DC voltage level provided by one of the at least one DC power outputs is sufficiently large such that the one of the at least one DC power outputs provides a DC voltage level (at the DC power input, of a radio, electrically coupled to the one of the at least one power output) that exceeds a minimum operating voltage rating of the radio. Optionally, a constant DC voltage level may be provided at all power outputs or a subset thereof; in the case of the latter, certain blocks of method 550 would be repeated for those power outputs at which a constant DC voltage level was not provided and until a resistance of electrical conductors is determined for each of the electrical conductors coupling a unique power output to a unique measurement sensor. Optionally, the constant DC voltage level provided at each of two or more power outputs may be different.

In block 550B, measure, during a time period, a set of direct current levels drawn from each power output which provides the constant DC voltage level. Each set of direct current levels is associated with a power output from which it was drawn.

In block 550C, a set of data indicative of voltage levels measured, during the time period at radio ends of a unique set of electrical conductors through which DC electrical power is provided from one of the at least one power output and through the first ends to the radio ends of the unique set of electrical conductors, is received at each logical or physical data port of the DC-DC voltage converter system. A number of logical or physical data ports is equal to or greater than a number of power outputs of the DC-DC voltage converter system, e.g., providing a constant DC voltage level. Because there is no mapping between logical or physical data ports and power output ports of the DC-DC voltage converter system, even if in block 550A a constant DC voltage level is provided to a subset of all power outputs of the DC-DC voltage converter system, a set of data is received at each logical or physical data port of the DC-DC voltage converter system. Optionally, each set of data indicative of voltage levels includes voltage levels. Optionally, each set of data is measured and provided by a unique measurement sensor. Optionally, each logical data port may be implemented as described elsewhere herein.

The logical or physical data port at which a set of data indicative of voltage levels was received need not be and may not be associated with such set. Even if associated with the set, the logical or physical data port may optionally be obfuscated by removing or replacing a label associated with such a data port with another label, e.g., randomly generated, that bears no association with the data port at which such set was received.

In optional block 550D, whether a measure of dispersion (MD) for each set of direct current (DC) levels measured during the time period exceeds a direct current dispersion threshold level is determined. This block 550D determines whether there is sufficient variation in each set of direct current levels is adequate to allow performance of block 550E, i.e., determining a pair of a set of data indicative of voltage levels and a set of DC levels that have a highest statistical dependence. The direct current dispersion threshold level may be set by a designer and/or a user of the DC-DC voltage converter system. Measure of dispersion with respect to a set of direct current levels means a measure of variation of the set of direct current levels. Such measure of dispersion may be characterized in different ways, e.g., by determining a standard deviation or variance of a set of direct current level, or by determining a magnitude of a difference between the highest direct current level of the set and the lowest direct current level of the set. If the measure of dispersion of each set of direct current levels measured during the time period is not greater than the direct current dispersion threshold level, then proceed to block 550A, e.g., which provides a constant DC voltage level at the same power outputs which were previously provided a constant DC voltage level in the last operation of block 550A; optionally, also increase the amount of time of the time period, e.g., by 1.5×, 2×, 2.5×, 3×, etc., for at least the next performance of block 550A. If the measure of dispersion of each set of direct current levels measured during the time period is greater than the direct current dispersion threshold level, then proceed to block 550E. Optionally, block 550D includes determine a measure of dispersion for each set od DC levels measured during the time period.

In block 550E, at least two pairs are determined, wherein each pair includes (i) a unique set of data indicative of voltage levels measured during the time period and (ii) a unique set of direct current levels, wherein each pair has a largest statistical dependence, e.g., correlation, for the unique set of data indicative of voltage levels with respect to all sets of direct current levels or for the unique set of current levels with respect to all sets of data indicative of voltage levels. Optionally, this is accomplished by determining a set of statistical dependencies for each set of direct current levels. Each set of statistical dependencies for a set of direct current levels is obtained by determining a statistical dependence of each set of data indicative of voltage levels measured during the time period with respect to a set of direct current levels. Thus, statistical dependencies are determined for two or more pairs of (i) a set of data indicative of voltage levels measured during the time period and (ii) the set of direct current levels. Then, the pair, of (i) a set of data indicative of voltage levels measured during the time period and (ii) the set of direct current levels, having the largest statistical dependence is determined. Statistical dependence means a statistical relationship, e.g., as determined from a correlation coefficient, a magnitude of the correlation coefficient, a coefficient of determination (or r², i.e., the square of a correlation coefficient), a mean squared error, a root mean squared error, a mean absolute error, and/or any other indicia of statistical relationship.

Optionally, whether each largest statistical dependence determined for each set of direct current levels is within a statistical dependence threshold range is determined. If each largest statistical dependence is within the statistical dependence threshold range, then proceed to block 550F. If each largest statistical dependence is not within the statistical dependence threshold range, then then proceed to block 550A, and repeat blocks 550A-550C, and 550E and optionally repeat block 550D for each power output at which a constant DC voltage level was provided at the last performance of block 550A. Optionally, increase the time period by 1.5×, 2×, 3×, etc., when repeating such blocks.

In optional block 550F, whether there are any other power outputs of the DC-DC voltage converter system from which direct current levels need to be measured is determined. Block 550F is not required if a set of direct current levels drawn from each power output of the DC-DC voltage converter system were measured in block 550B. Upon determining that there is at least one power output of the DC-DC voltage converter system from which a set of direct current levels need to measured, then proceed to block 550A; blocks 550A-550C, 550E, and 550F (and optionally block 550D) are repeated once or more times until a set of direct current levels drawn from each power output of the DC-DC voltage converter system has been measured and paired with a set of data indicative of voltage levels (in block 550E).

In block 550G, for each of the at least two pairs, (a) a linear regression is performed on the unique set of direct current levels and the unique set of data indicative of voltage levels of a pair, and (b) using a slope coefficient, or a magnitude of a slope coefficient, derived from the linear regression, a resistance, of a set of electrical conductors electrically coupled to a power output with which the unique set of direct current levels was drawn, is determined. Linear regression determines a slope coefficient, a, and a DC voltage axis intercept, b, where DC Voltage=−a*(DC)+b.

Optionally, for each power output, the resistance of the electrical conductors may be determined by performing a linear regression on the set of direct current levels (measured at a power output) and the set of data indicative of voltage levels measured during the time period. Optionally, other techniques may be used to determine such resistance of each electrical conductor.

In optional block 550H, whether a resistance that is valid is determined for electrical conductors electrically coupled to each power output is determined. Optionally, determining whether a resistance is valid comprises determining whether the resistance is determined to be within a predetermined range of resistances, e.g., between 0.1 ohm and 1 ohm. If it is determined that a resistance is not valid for electrical conductors electrically coupled to each power output, then proceed to block 550A, and repeat blocks 550A-550C, 550E, and 550F, and optionally repeat blocks 550D and/or 550F for each power output coupled to electrical conductors for which the resistance was determined to be not valid or for all power outputs. Optionally, increase the time period by 1.5×, 2×, 3×, etc., when repeating such blocks. If it is determined that all resistances are valid, then stop. Alternatively and optionally, determining whether a resistance is valid includes determining whether a set of data indicative of voltage levels measured during the time period or a set of direct current levels is an element of more than one pair (and thus is not unique); if used in more than one pair, then repeating for each power output coupled to electrical providing the constant DC voltage level, measuring during a time period a set of direct current levels and associating each set of direct current levels, receiving at each logical or physical data port the set of data indicative of voltage levels, determining the pair, and optionally determining the resistance

The processing system (or processing circuitry) disclosed herein may comprise state machines, neural network, and/or other types of computing systems. Such processing system may comprise processing circuitry coupled to memory circuitry. The processing circuitry may include one or more microprocessors, microcontrollers, digital signal processing (DSP) elements, application-specific integrated circuits (ASICs), and/or field programmable gate arrays (FPGAs). The processor system may include or function with software programs, firmware, or other computer readable instructions, e.g., stored in the memory circuitry, for carrying out various process tasks, calculations, and control functions, used in the methods described herein. These instructions are typically tangibly embodied on any storage media (or computer readable medium) used for storage of computer readable instructions or data structures.

The memory circuitry can be implemented with any available storage media (or computer readable medium) that can be accessed by a general purpose or special purpose computer or processor, or any programmable logic device. Suitable computer readable medium may include storage or memory media such as semiconductor, magnetic, and/or optical media. For example, computer readable media may include conventional hard disks, volatile or non-volatile media such as Random Access Memory (RAM) (including, but not limited to, Dynamic Random Access Memory (DRAM)), Read Only Memory (ROM), Electrically Erasable Programmable ROM (EEPROM), and/or flash memory.

Methods of the invention can be implemented in computer readable instructions, such as program modules or applications, which may be stored in the computer readable medium and executed by the processing circuitry. Generally, program modules or applications include routines, programs, objects, data components, data structures, algorithms, and the like, which perform particular tasks or implement particular abstract data types.

### EXAMPLE EMBODIMENTS

Example 1 includes a method for determining a resistance of at least two sets of electrical conductors each of which whose first ends are electrically coupled to a unique power output of a DC-DC voltage converter system and whose radio ends are electrically coupled to a DC power input of a unique radio, the method comprising: providing a constant direct current (DC) voltage level at each of at least two power outputs of the DC-DC voltage converter system; measuring, during a time period, a set of direct current levels drawn from each power output which provides a constant DC voltage level, and associating each set of direct current levels with a power output from which direct current was drawn; receiving, at each logical or physical data port of the DC-DC voltage converter system, a set of data indicative of voltage levels measured during the time period at radio ends of a unique set of electrical conductors through which DC electrical power is provided from one of the at least two power outputs and through the first ends to the radio ends of the unique set of electrical conductors; determining at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of direct current levels with respect to all sets of data indicative of voltage levels; and for each of the at least two pairs, performing linear regression on the unique set of direct current levels and the unique set of data indicative of voltage levels of a pair, and then determining, from a slope coefficient, or a magnitude thereof, derived from the linear regression, a resistance of a set of electrical conductors electrically coupled to a power output with which the unique set of direct current levels was drawn.

Example 2 includes the method of Example 1, wherein the constant DC voltage level provided at each of at least two power outputs are different.

Example 3 includes the method of any of Examples 1-2, wherein the set of data indicative of voltage levels comprises voltage levels.

Example 4 includes the method of any of Examples 1-3, further comprising removing or obscuring an association between each set of data indicative of voltage levels and a unique logical or physical feedback data port of the DC-DC voltage converter system.

Example 5 includes the method of any of Examples 1-4, further comprising: determining whether a measure of dispersion for each set of direct current levels measured during the time period exceeds a direct current dispersion threshold level; and determining that the measure of dispersion for each set of direct current levels does not exceed the direct current dispersion threshold level, then repeating providing the constant DC voltage level, measuring during a time period the set of direct current levels and associating each set of direct current levels, and receiving at each logical or physical data port the set of data indicative of voltage levels.

Example 6 includes the method of any of Examples 1-5, further comprising: determining whether each resistance is within a predetermined range of resistances; and determining that at least one resistance is not within the predetermined range of resistances, then repeating for each power output coupled to electrical conductors for which the resistance was determined to be not valid or for each of all power outputs, measuring during another time period a set of direct current levels and associating each set of direct current levels, receiving at each logical or physical data port the set of data indicative of voltage levels, determining the pair, and determining the resistance.

Example 7 includes the method of any of Examples 1-6, wherein correlation is one of: a correlation coefficient, a magnitude of the correlation coefficient, and a coefficient of determination.

Example 8 includes a non-transitory computer readable medium storing a program causing at least one processor to execute a process to determine a resistance of at least two sets of electrical conductors each of which whose first ends are electrically coupled to a unique power output of a DC-DC voltage converter system and whose radio ends are electrically coupled to a DC power input of a unique radio, the process comprising: causing provision of a constant direct current (DC) voltage level at each of at least two power output of the DC-DC voltage converter system; receiving a set of direct current levels measured during a time period and drawn from each power output which provides a constant DC voltage level, and associating each set of direct current levels with a power output from which direct current was drawn; receiving, from each logical or physical data port of the DC-DC voltage converter system, a set of data indicative of voltage levels measured during the time period at radio ends of a unique set of electrical conductors though which DC electrical power is provided from one of the at least two power output and through the first ends to the radio ends of the unique set of electrical conductors; determining at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of current levels with respect to all sets of data indicative of voltage levels; and for each of the at least two pairs, (a) performing linear regression on the unique set of direct current levels and the unique set of data indicative of voltage levels of a pair, and then (b) determining, from a slope coefficient, or a magnitude thereof, derived from the linear regression, a resistance of a set of electrical conductors electrically coupled to a power output with which the unique set of direct current levels was drawn.

Example 9 includes the non-transitory computer readable medium of Example 8, wherein the constant DC voltage level provided at each of at least two power outputs are different.

Example 10 includes the non-transitory computer readable medium of any of Examples 8-9, wherein the set of data indicative of voltage levels comprises voltage levels.

Example 11 includes the non-transitory computer readable medium of any of Examples 8-10, wherein the process further comprises removing or obscuring an association between each set of data indicative of voltage levels and a unique logical or physical feedback data port of the DC-DC voltage converter system.

Example 12 includes the non-transitory computer readable medium of any of Examples 8-11, wherein the process further comprises: determining whether a measure of dispersion for each set of direct current levels measured during the time period exceeds a direct current dispersion threshold level; and determining that the measure of dispersion for each set of direct current levels does not exceed the direct current dispersion threshold level, then repeating providing the constant DC voltage level, measuring during a time period the set of direct current levels and associating each set of direct current levels, and receiving at each logical or physical data port the set of data indicative of voltage levels.

Example 13 includes the non-transitory computer readable medium of any of Examples 8-12, wherein the process further comprises: determining whether each resistance is within a predetermined range of resistances; and determining that at least one resistance is not within the predetermined range of resistances, then repeating for each power output coupled to electrical conductors for which the resistance was determined to be not valid or for each of all power outputs, measuring during another time period a set of direct current levels and associating each set of direct current levels, receiving at each logical or physical data port the set of data indicative of voltage levels, determining the pair, and determining the resistance.

Example 14 includes the non-transitory computer readable medium of any of Examples 8-13, wherein correlation is one of: a correlation coefficient, a magnitude of the correlation coefficient, and a coefficient of determination.

Example 15 includes a direct current (DC)-DC voltage converter system configured to determine a resistance of at least two sets of electrical conductors each of which whose first ends are electrically coupled to a unique power output of the DC-DC voltage converter system and whose radio ends are electrically coupled to a DC power input of a unique radio, comprising: at least two DC power outputs each of which is configured to be coupled through unique electrical conductors, at radio ends of the unique electrical conductors, to a unique measurement sensor and electrically coupled to a unique radio; at least two DC-DC voltage converters each of which is configured to provide DC power to a unique DC power output of the at least two DC power outputs; at least two logical or physical feedback ports each of which is configured to be communicatively coupled to the unique measurement sensor; and processing circuitry communicatively coupled to each DC-DC voltage converter, and configured to: cause provision of a constant direct current (DC) voltage level at each of at least two DC power outputs; receive a set of direct current levels measured during a time period and drawn from each power output which provides a constant DC voltage level, and associating each set of direct current levels with a power output from which direct current was drawn; receive, from each logical or physical data port, a set of data indicative of voltage levels measured during the time period at radio ends of a unique set of electrical conductors through which DC electrical power is provided from one of the at least two power output and through the first ends to the radio ends of the unique set of electrical conductors; determine at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of current levels with respect to all sets of data indicative of voltage levels; and for each of the at least two pairs, (a) performing linear regression on the unique set of direct current levels and the unique set of data indicative of voltage levels of a pair, and then (b) determining, from a slope coefficient, or a magnitude thereof, derived from the linear regression, a resistance of a set of electrical conductors electrically coupled to a power output with which the unique set of direct current levels was drawn.

Example 16 includes the DC-DC voltage converter system of Example 15, wherein the constant DC voltage level provided at each of at least two power outputs are different.

Example 17 includes the DC-DC voltage converter system of any of Examples 15-16, wherein the set of data indicative of voltage levels comprises voltage levels.

Example 18 includes the DC-DC voltage converter system of any of Examples 15-17, wherein the processing circuitry is further configured to remove or obscure an association between each set of data indicative of voltage levels and a unique logical or physical feedback data port of the DC-DC voltage converter system.

Example 19 includes the DC-DC voltage converter system of any of Examples 15-18, wherein the processing circuitry is further configured to: determine whether a measure of dispersion for each set of direct current levels measured during the time period exceeds a direct current dispersion threshold level; and determining that the measure of dispersion for each set of direct current levels does not exceed the direct current dispersion threshold level, then repeat providing the constant DC voltage level, measuring during a time period the set of direct current levels and associating each set of direct current levels, and receiving at each logical or physical data port the set of data indicative of voltage levels.

Example 20 includes the DC-DC voltage converter system of any of Examples 15-19, wherein the processing circuitry is further configured to: determine whether each resistance is within a predetermined range of resistances; and determining that at least one resistance is not within the predetermined range of resistances, then repeating for each power output coupled to electrical conductors for which the resistance was determined to be not valid or for each of all power outputs, measuring during another time period a set of direct current levels and associating each set of direct current levels, receiving at each logical or physical data port the set of data indicative of voltage levels, determining the pair, and determining the resistance.

Example 21 includes the DC-DC voltage converter system of any of Examples 15-20, wherein correlation is one of: a correlation coefficient, a magnitude of the correlation coefficient, and a coefficient of determination.

Example 22 includes a method for correctly associating a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system, the method comprising: providing, during a time period, electrical DC power, including a constant DC voltage level, at at least two DC power outputs of the DC-DC voltage converter system, wherein direct current levels drawn during the time period from each of the at least two DC power outputs is different than the direct current levels drawn during the time period from any of other of the at least two DC power outputs; receiving measurement data, measured during the time period, (a) at each of the at least two feedback ports, of the DC-DC voltage converter system, from a unique one of measurement sensors and (b) that is derived from a DC voltage level, measured by the unique one of the measurement sensors, proximate to radio ends of a unique set of electrical conductors; measuring, during the time period, the direct current levels drawn from each of the at least two DC power outputs of the DC-DC voltage converter system; and using the measurement data measured during the time period received at each of the at least two feedback ports and the direct current levels measured being drawn, during the time period, from each of the at least two DC power outputs, determining an association between each of the at least two DC power outputs and a unique one of the at least two feedback ports, wherein the at least two feedback ports are either logical feedback ports or physical feedback ports; wherein responsive to other measurement data received at one of the at least two feedback ports at another time, the association is configured to be used to adjust a DC voltage level provided by a DC-DC voltage converter to one of the at least two DC power outputs which has been associated with the one of the at least two feedback ports.

Example 23 includes the method of Example 22, further comprising: receiving an initial association between each of the at least two DC power outputs and a unique one of the at least two feedback ports; and using the association which was determined, identifying a correction to the initial association.

Example 24 includes the method of Example 23, further comprising transmitting the correction to at least one of an installer, a network operator, and a system.

Example 25 includes the method of any of Examples 22-24, wherein determining the association between each of the at least two DC power outputs and the unique one of the at least two feedback ports comprises: determining a correlation of each possible combination of (a) the direct current levels measured being drawn, during the time period, from each of the at least two DC power outputs and (b) the measurement data measured during the time period and received at each of the at least two feedback ports, wherein the at least two DC power outputs at which the electrical DC power, including the constant DC voltage level, is provided equals N power outputs, and wherein N is an integer value; determining N pairs of each such direct current levels and the measurement data having largest correlations of all correlations determined; and for each of the N pairs, identifying one of the at least two DC power outputs associated with a direct current level of a pair and a feedback port associated with the measurement data of the pair.

Example 26 includes the method of any of Examples 22-25, wherein determining the association between each of the at least two DC power outputs and the unique one of the at least two feedback ports comprises: performing a linear regression of each possible combination of (a) the direct current levels measured being drawn, during the time period, from each of the at least two DC power outputs and (b) measured data measured during the time period and received at each of the at least two feedback ports, and then determining a standard deviation, of the direct current levels and the measurement data with respect to a line determined by the linear regression, wherein the at least two DC power outputs at which the electrical DC power, including the constant DC voltage level, is provided equals M power outputs, and wherein M is an integer value; determining M pairs of each such direct current levels and the measured data having smallest standard deviations of all standard deviations determined; and for each of the M pairs, identifying one of the at least two DC power outputs associated with a direct current level of a pair and a feedback port associated with the measured data of the pair.

Example 27 includes the method of any of Examples 22-26, wherein the constant DC voltage level provided at each DC power output are not equal.

Example 28 includes the method of any of Examples 22-27, further comprising after determining the association, using the association and the other measurement data received at the other time at one of the at least two feedback ports to adjust a DC voltage level provided by a DC-DC voltage converter to the one of the at least two DC power outputs which has been associated with the one of the at least two feedback ports.

Example 29 includes a non-transitory computer readable medium storing a program causing at least one processor to execute a process to correctly associate a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system, the process comprising: causing, during a time period, provision of electrical DC power, including a constant DC voltage level, at at least two DC power outputs of the DC-DC voltage converter system, wherein direct current levels drawn during the time period from each of the at least two DC power outputs is different than the direct current levels drawn during the time period from any of other of the at least two DC power outputs; receiving measurement data, measured during the time period, (a) at each of the at least two feedback ports, of the DC-DC voltage converter system, from a unique one of measurement sensors and (b) that is derived from a DC voltage level, measured by the unique one of the measurement sensors, proximate to radio ends of a unique set of electrical conductors; receiving, during the time period, measurements of the direct current levels drawn from each of the at least two DC power outputs of the DC-DC voltage converter system; and using the measurement data measured during the time period received at each of the at least two feedback ports and the direct current levels measured being drawn, during the time period, from each of the at least two DC power outputs, determining an association between each of the at least two DC power outputs and a unique one of the at least two feedback ports, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to one of the at least two DC power outputs which has been associated with the one of the at least two feedback ports.

Example 30 includes the non-transitory computer readable medium of Example 29, wherein the process further comprises: receiving an initial association between each of the at least two DC power outputs and a unique one of the at least two feedback ports; and using the association which was determined, identifying a correction to the initial association.

Example 31 includes the non-transitory computer readable medium of any of Examples 29-30, wherein the process further comprises causing transmission of the correction to at least one of an installer, a network operator, and a system.

Example 32 includes the non-transitory computer readable medium of any of Examples 29-31, wherein determining the association between each of the at least two DC power outputs and the unique one of the at least two feedback ports comprises: determining a correlation of each possible combination of (a) the direct current levels measured being drawn, during the time period, from each of the at least two DC power outputs and (b) the measurement data measured during the time period and received at each of the at least two feedback ports, wherein the at least two DC power outputs at which the electrical DC power, including the constant DC voltage level, is provided equals N power outputs, and wherein N is an integer value; determining N pairs of each such direct current levels and the measurement data having largest correlations of all correlations determined; and for each of the N pairs, identifying one of the at least two DC power outputs associated with a direct current level of a pair and a feedback port associated with the measurement data of the pair.

Example 33 includes the non-transitory computer readable medium of any of Examples 29-32, wherein determining the association between each of the at least two DC power outputs and the unique one of the at least two feedback ports comprises: performing a linear regression of each possible combination of (a) the direct current levels measured being drawn, during the time period, from each of the at least two DC power outputs and (b) measured data measured during the time period and received at each of the at least two feedback ports, and then determining a standard deviation, of the direct current levels and the measurement data with respect to a line determined by the linear regression, wherein the at least two DC power outputs at which the electrical DC power, including the constant DC voltage level, is provided equals M power outputs, and wherein M is an integer value; determining M pairs of each such direct current levels and the measurement data having smallest standard deviations of all standard deviations determined; and for each of the M pairs, identifying one of the at least two DC power outputs associated with a direct current level of a pair and a feedback port associated with the measurement data of the pair.

Example 34 includes the non-transitory computer readable medium of any of Examples 29-33, wherein the constant DC voltage level provided at each DC power output are not equal.

Example 35 includes the non-transitory computer readable medium of any of Examples 29-34, wherein the process further comprises, after determining the association, using the association and the other measurement data received at the other time at the one of the at least two feedback ports to adjust a DC voltage level provided by a DC-DC voltage converter to one of the at least two DC power outputs which has been associated with the one of the at least two feedback ports.

Example 36 includes a direct current (DC)-DC voltage converter system comprising: at least two DC power outputs each of which is configured to be coupled through unique electrical conductors, at radio ends of the unique electrical conductors, to a unique measurement sensor and electrically coupled to a unique radio; at least two DC-DC voltage converters each of which is configured to provide DC power to a unique DC power output of the at least two DC power outputs; at least two feedback ports each of which is configured to be communicatively coupled to the unique measurement sensor; and processing circuitry communicatively coupled to each DC-DC voltage converter, and configured to: cause, during a time period, provision of electrical DC power, including a constant DC voltage level, at at least two DC power outputs of the DC-DC voltage converter system, wherein direct current levels drawn during the time period from each of the at least two DC power outputs is different than the direct current levels drawn during the time period from any of other of the at least two DC power outputs; receive measurement data, measured during the time period, (a) at each of the at least two feedback ports, of the DC-DC voltage converter system, from a unique one of measurement sensors and (b) that is derived from a DC voltage level, measured by the unique one of measurement sensors, proximate to radio ends of a unique set of electrical conductors; receive, during the time period, measurements of the direct current levels drawn from each of the at least two DC power outputs of the DC-DC voltage converter system; and using the measurement data measured during the time period received at each of the at least two feedback ports and the direct current levels measured being drawn, during the time period, from each of the at least two DC power outputs, determine an association between each of the at least two DC power outputs and a unique one of the at least two feedback ports, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to one of the at least two DC power outputs which has been associated with the one of the at least two feedback ports.

Example 37 includes the DC-DC voltage converter system of Example 36, wherein the processing circuitry is further configured to: receive an initial association between each of the at least two DC power outputs and a unique one of the at least two feedback ports; and using the association which was determined, identify a correction to the initial association.

Example 38 includes the DC-DC voltage converter system of any of Examples 36-37, wherein the processing circuitry is further configured to cause transmission of the correction to at least one of an installer, a network operator, and a system.

Example 39 includes the DC-DC voltage converter system of any of Examples 36-38, wherein determining the association between each of the at least two DC power outputs and the unique one of the at least two feedback ports comprises: determine a correlation of each possible combination of (a) direct current levels measured being drawn from each of the at least two DC power outputs and (b) measurement data received at each of the at least two feedback ports, wherein the at least two DC power outputs at which the electrical DC power, including the constant DC voltage level, is provided equals N power outputs, and wherein N is an integer value; determine N pairs of each such direct current levels and the measurement data having largest correlations of all correlations determined; and for each of the N pairs, identify one of the at least two DC power outputs associated with a direct current level of a pair and a feedback port associated with the measurement data of the pair.

Example 40 includes the DC-DC voltage converter system of any of Examples 36-39, wherein determining the association between each of the at least two DC power outputs and the unique one of the at least two feedback ports comprises: performing a linear regression of each possible combination of (a) the direct current levels measured being drawn, during the time period, from each of the at least two DC power outputs and (b) measured data measured during the time period and received at each of the at least two feedback ports, and then determining a standard deviation, of the direct current levels and the measurement data with respect to a line determined by the linear regression, wherein the at least two DC power outputs at which the electrical DC power, including the constant DC voltage level, is provided equals M power outputs, and wherein M is an integer value; determine M pairs of each such direct current levels and the measurement data having smallest standard deviations of all standard deviations determined; and for each of the M pairs, identify one of the at least two DC power outputs associated with a direct current level of a pair and a feedback port associated with the measurement data of the pair.

Example 41 includes the DC-DC voltage converter system of any of Examples 36-40, wherein the constant DC voltage level provided at each DC power output are not equal.

Example 42 includes the DC-DC voltage converter system of any of Examples 36-41, wherein the processing circuitry is further configured to, after determining the association, using the association and the other measurement data received at the other time at the one of the at least two feedback ports to cause adjustment of a DC voltage level provided by a DC-DC voltage converter to one of the at least two DC power outputs which has been associated with the one of the at least two feedback ports.

Example 43 includes a direct current (DC)-DC voltage converter system comprising: at least two DC power outputs each of which is configured to be coupled through unique electrical conductors, at radio ends of the unique electrical conductors, to a unique measurement sensor and electrically coupled to a unique radio; at least two DC-DC voltage converters each of which is configured to provide DC power to a unique DC power output of the at least two DC power outputs; at least two feedback ports each of which is configured to be communicatively coupled to the unique measurement sensor; and processing circuitry communicatively coupled to each DC-DC voltage converter, and configured to: cause provision of electrical DC power, including a constant DC voltage level, during a unique one of sequential time periods at a unique one of the at least two DC power outputs of the DC-DC voltage converter system; receive, during each time period, measurement data (a) at each of the at least two feedback ports, of the DC-DC voltage converter system, from a unique one of measurement sensors and (b) each of which is derived from a DC voltage level measured by the unique one of the measurement sensors electrically connected to and proximate to radio ends of a unique set of electrical conductors; for each time period, identify a feedback port receiving measurement data derived from one of DC voltage levels which exceeds a voltage threshold level; for each time period, determine an association between the feedback port which was identified and one of the at least two DC output ports providing the constant DC voltage level during a unique time period, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to a DC power output, of the at least two DC power outputs, which has been associated with the one of the at least two feedback ports.

Example 44 includes a method for correctly associating a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system, the method comprising: providing electrical DC power, including a constant DC voltage level, during a unique one of sequential time periods at a unique one of the at least two DC power outputs of the DC-DC voltage converter system; receiving, during each time period, measurement data (a) at each of the at least two feedback ports, of the DC-DC voltage converter system, from a unique one of measurement sensors and (b) each of which is derived from a DC voltage level measured by the unique one of the measurement sensors electrically connected to and proximate to radio ends of a unique set of electrical conductors; for each time period, identifying a feedback port receiving measurement data derived from one of DC voltage levels which exceeds a voltage threshold level; and for each time period, determining an association between the feedback port which was identified and one of the at least two DC output ports providing the constant DC voltage level during a unique time period, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to a DC power output, of the at least two DC power outputs, which has been associated with the one of the at least two feedback ports.

Example 45 includes a non-transitory computer readable medium storing a program causing at least one processor to execute a process to correctly associate a feedback port of a direct current (DC)-DC voltage converter system with a DC power output of the DC-DC voltage converter system, wherein the DC-DC voltage converter system comprises at least two feedback ports and at least two DC-DC voltage converters each of which is coupled to a unique DC power output, wherein each of at least two DC power outputs are coupled by unique electrical conductors to a unique measurement sensor and a DC power input of a unique radio, wherein the unique measurement sensor and the DC power input of the unique radio are electrically coupled to radio ends of the unique electrical conductors, and wherein the radio ends are remotely located from the DC-DC voltage converter system, the process comprising: causing provision of electrical DC power, including a constant DC voltage level, during a unique one of sequential time periods at a unique one of the at least two DC power outputs of the DC-DC voltage converter system; receiving, during each time period, measurement data (a) at each of the at least two feedback ports, of the DC-DC voltage converter system, from a unique one of measurement sensors and (b) each of which is derived from a DC voltage level measured by the unique one of the measurement sensors electrically connected to and proximate to radio ends of a unique set of electrical conductors; for each time period, identifying a feedback port receiving measurement data derived from one of DC voltage levels which exceeds a voltage threshold level; and for each time period, determining an association between the feedback port which was identified and one of the at least two DC output ports providing the constant DC voltage level during a unique time period, wherein the at least two feedback ports are either logical feedback ports or physical feedback ports; wherein responsive to other measurement data received at another time at one of the at least two feedback ports, the association is configured to be used to adjust a DC voltage level provided by a DC-DC voltage converter to a DC power output, of the at least two DC power outputs, which has been associated with the one of the at least two feedback ports.

Example 46 includes a method for correctly associating a feedback port of a direct current (DC)-DC voltage converter system with a DC power output port of the DC-DC voltage converter system, wherein the DC-DC voltage converter system comprises at least two feedback ports and at least two DC-DC voltage converters each of which is coupled to a unique DC power output, the method comprising: providing a voltage waveform at at least one of at least two DC power outputs of the DC-DC voltage converter system, wherein each DC power output (a) receives a voltage waveform from a unique DC-DC voltage converter of the DC-DC voltage converter system and (b) is configured to be electrically coupled to a DC power input of a unique radio; receiving measurement data (a) at a feedback port, of the DC-DC voltage converter system, from a measurement sensor uniquely communicatively coupled to the feedback port and (b) that is derived from a voltage waveform received by the measurement sensor which is uniquely coupled to a DC power output; determining an association between the DC power output and the feedback port using the measurement data which was received and the voltage waveform which was provided; and at least one of: (a) wherein providing the voltage waveform at at least one of the at least two DC power outputs comprises providing a different voltage waveform, simultaneously, at each of the at least two DC power outputs; and (b) wherein determining the association between the DC power output and the feedback port comprises comparing at least one of: (i) over time, a time varying parameter of the measurement data with a time varying parameter of the voltage waveform and (ii) a characteristic derived, over time, from the time varying parameter of the measurement data with a characteristic derived, over time, from the time varying parameter of the voltage waveform, wherein each of the measurement data and the voltage waveform comprise at least one time varying parameter; wherein the feedback ports are all logical feedback ports or all physical feedback ports.

Example 47 includes the method of Example 46, further comprising: receiving an initial association between the DC power output and the feedback port; and using the association which was determined, identifying a correction to the initial association.

Example 48 includes the method of any of Examples 46-47, further comprising transmitting the correction to at least one of an installer, a network operator, and a system.

Example 49 includes the method of any of Examples 46-48, wherein comparing comprises performing at least one of (a) pattern matching, correlation, and statistical analysis.

Example 50 includes the method of any of Examples 46-49, further comprising, after determining the association, using other measurement data received at the feedback port to adjust a DC voltage level provided by a DC-DC voltage converter to the DC power output.

Example 51 includes the method of Example 50, wherein the DC voltage level exceeds a nominal DC voltage level which a manufacturer of a radio specifies should be provided to a DC power input of the radio.

Example 52 includes a non-transitory computer readable medium storing a program causing at least one processor to execute a process to correctly associating one or more feedback ports of a direct current (DC)-DC voltage converter system with a DC power output port of the DC-DC voltage converter system, wherein the DC-DC voltage converter system comprises at least two feedback ports, and at least two DC-DC voltage converters each of which is coupled to a unique DC power output, the process comprising: causing a voltage waveform to be provided at at least one of at least two DC power outputs of the DC-DC voltage converter system, wherein each DC power output (a) receives a voltage waveform from a unique DC-DC voltage converter of the DC-DC voltage converter system and (b) is configured to be electrically coupled to a DC power input of a unique radio; receiving measurement data received (a) at a feedback port, of the DC-DC voltage converter system, from a measurement sensor uniquely communicatively coupled to the feedback port and (b) that is derived from a voltage waveform received by the measurement sensor which is uniquely coupled to a DC power output; determining an association between the DC power output and the feedback port using the measurement data which was received and the voltage waveform which was caused to be provided; and at least one of: wherein causing the voltage waveform to be provided at at least one of the at least two DC power outputs comprises causing a different voltage waveform to be provided, simultaneously, at each of the at least two DC power outputs; and wherein determining the association between the DC power output and the feedback port comprises comparing at least one of: (i) over time, a time varying parameter of the measurement data with a time varying parameter of the voltage waveform and (ii) a characteristic derived, over time, from the time varying parameter of the measurement data with a characteristic derived, over time, from the time varying parameter of the voltage waveform, wherein each of the measurement data and the voltage waveform comprise at least one time varying parameter; wherein feedback ports are all logical feedback ports or all physical feedback ports.

Example 53 includes the non-transitory computer readable medium of Examples 52, wherein the process further comprises: receiving an initial association between the DC power output and the feedback port; and using the association which was determined, identifying a correction to the initial association.

Example 54 includes the non-transitory computer readable medium of any of Examples 52-53, wherein the process further comprises causing transmission of the correction to at least one of an installer, a network operator, and a system.

Example 55 includes the non-transitory computer readable medium of any of Examples 52-54, wherein comparing comprises performing at least one of (a) pattern matching, correlation, and statistical analysis.

Example 56 includes the non-transitory computer readable medium of any of Examples 52-55, wherein the process further comprises, after determining the association, using other measurement data received at the feedback port to cause adjustment of a DC voltage level provided by a DC-DC voltage converter to the DC power output.

Example 57 includes the non-transitory computer readable medium of Example 56, wherein the DC voltage level exceeds a nominal DC voltage level which a manufacturer of a radio specifies should be provided to a DC power input of the radio.

Example 58 includes a direct current (DC)-DC voltage converter system comprising: at least two DC power outputs each of which is configured to be coupled through unique power conductors to a unique measurement sensor and electrically coupled to a unique radio; at least two DC-DC voltage converters configured to provide DC power to a unique DC power output of the at least two DC power outputs; at least two feedback ports each of which is configured to be communicatively coupled to the unique measurement sensor; and processing circuitry communicatively coupled to each DC-DC voltage converter and each DC-DC voltage converter, and configured to: cause a voltage waveform to be provided at at least one of at least two DC power outputs of the DC-DC voltage converter system, wherein each DC power output (a) receives a voltage waveform from a unique DC-DC voltage converter of the DC-DC voltage converter system and (b) is configured to be electrically coupled to a DC power input of a unique radio; receive measurement data received (a) at a feedback port, of the DC-DC voltage converter system, from a measurement sensor uniquely communicatively coupled to the feedback port and (b) that is derived from a voltage waveform received by the measurement sensor which is uniquely coupled to a DC power output; determine an association between the DC power output and the feedback port using the measurement data which was received and the voltage waveform which was caused to be provided; and at least one of: wherein causing the voltage waveform to be provided at at least one of the at least two DC power outputs comprises causing a different voltage waveform to be provided, simultaneously, at each of the at least two DC power outputs; and wherein determining the association between the DC power output and the feedback port comprises comparing at least one of: (i) over time, a time varying parameter of the measurement data with a time varying parameter of the voltage waveform and (ii) a characteristic derived, over time, from the time varying parameter of the measurement data with a characteristic derived, over time, from the time varying parameter of the voltage waveform, wherein each of the measurement data and the voltage waveform comprise at least one time varying parameter; wherein feedback ports are all logical feedback ports or all physical feedback ports.

Example 59 includes the DC-DC voltage converter system of Example 58, wherein the processing circuitry is further configured to: receive an initial association between the DC power output and the feedback port; and using the association which was determined, identify a correction to the initial association.

Example 60 includes the DC-DC voltage converter system of any of Examples 58-59, wherein the processing circuitry is further configured to cause transmission of the correction to at least one of an installer, a network operator, and a system.

Example 61 includes the DC-DC voltage converter system of any of Examples 58-59, wherein comparing comprises performing at least one of (a) pattern matching, correlation, and statistical analysis.

Example 62 includes the DC-DC voltage converter system of any of Examples 58-61, wherein determining the at least one association between a corresponding DC power output and a corresponding feedback port is performed using at least one of pattern matching and correlation.

Example 63 includes the DC-DC voltage converter system of any of Examples 58-62, wherein the processing circuitry is further configured to, after determining the association, using other measurement data received at the feedback port to adjust a DC voltage level provided by a DC-DC voltage converter to the DC power output.

Example 64 includes the DC-DC voltage converter system of any of Examples 62-63, wherein the DC voltage level exceeds a nominal DC voltage level which a manufacturer of a radio specifies should be provided to a DC power input of the radio.

A number of embodiments of the invention defined by the following claims have been described. Nevertheless, it will be understood that various modifications to the described embodiments may be made without departing from the spirit and scope of the claimed invention. Accordingly, other embodiments are within the scope of the following claims.

1. A method for determining a resistance of at least two sets of electrical conductors each of which whose first ends are electrically coupled to a unique power output of a DC-DC voltage converter system and whose radio ends are electrically coupled to a DC power input of a unique radio, the method comprising:
providing a constant direct current (DC) voltage level at each of at least two power outputs of the DC-DC voltage converter system;
measuring, during a time period, a set of direct current levels drawn from each power output which provides a constant DC voltage level, and associating each set of direct current levels with a power output from which direct current was drawn;
receiving, at each logical or physical data port of the DC-DC voltage converter system, a set of data indicative of voltage levels measured during the time period at radio ends of a unique set of electrical conductors through which DC electrical power is provided from one of the at least two power outputs and through the first ends to the radio ends of the unique set of electrical conductors;
determining at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of direct current levels with respect to all sets of data indicative of voltage levels; and
for each of the at least two pairs, performing linear regression on the unique set of direct current levels and the unique set of data indicative of voltage levels of a pair, and then determining, from a slope coefficient, or a magnitude thereof, derived from the linear regression, a resistance of a set of electrical conductors electrically coupled to a power output with which the unique set of direct current levels was drawn.

2. The method of claim 1, wherein the constant DC voltage level provided at each of at least two power outputs are different.

3. The method of claim 1, wherein the set of data indicative of voltage levels comprises voltage levels.

4. The method of claim 1, further comprising removing or obscuring an association between each set of data indicative of voltage levels and a unique logical or physical feedback data port of the DC-DC voltage converter system.

5. The method of claim 1, further comprising:
determining whether a measure of dispersion for each set of direct current levels measured during the time period exceeds a direct current dispersion threshold level; and
determining that the measure of dispersion for each set of direct current levels does not exceed the direct current dispersion threshold level, then repeating providing the constant DC voltage level, measuring during a time period the set of direct current levels and associating each set of direct current levels, and receiving at each logical or physical data port the set of data indicative of voltage levels.

6. The method of claim 1, further comprising:
determining whether each resistance is within a predetermined range of resistances; and
determining that at least one resistance is not within the predetermined range of resistances, then repeating for each power output coupled to electrical conductors for which the resistance was determined to be not valid or for each of all power outputs, measuring during another time period a set of direct current levels and associating each set of direct current levels, receiving at each logical or physical data port the set of data indicative of voltage levels, determining the pair, and determining the resistance.

7. The method of claim 1, wherein correlation is one of: a correlation coefficient, a magnitude of the correlation coefficient, and a coefficient of determination.

8. A non-transitory computer readable medium storing a program causing at least one processor to execute a process to determine a resistance of at least two sets of electrical conductors each of which whose first ends are electrically coupled to a unique power output of a DC-DC voltage converter system and whose radio ends are electrically coupled to a DC power input of a unique radio, the process comprising:
causing provision of a constant direct current (DC) voltage level at each of at least two power output of the DC-DC voltage converter system;
receiving a set of direct current levels measured during a time period and drawn from each power output which provides a constant DC voltage level, and associating each set of direct current levels with a power output from which direct current was drawn;
receiving, from each logical or physical data port of the DC-DC voltage converter system, a set of data indicative of voltage levels measured during the time period at radio ends of a unique set of electrical conductors though which DC electrical power is provided from one of the at least two power output and through the first ends to the radio ends of the unique set of electrical conductors;
determining at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of current levels with respect to all sets of data indicative of voltage levels; and
for each of the at least two pairs, (a) performing linear regression on the unique set of direct current levels and the unique set of data indicative of voltage levels of a pair, and then (b) determining, from a slope coefficient, or a magnitude thereof, derived from the linear regression, a resistance of a set of electrical conductors electrically coupled to a power output with which the unique set of direct current levels was drawn.

9. The non-transitory computer readable medium of claim 8, wherein the constant DC voltage level provided at each of at least two power outputs are different.

10. The non-transitory computer readable medium of claim 8, wherein the set of data indicative of voltage levels comprises voltage levels.

11. The non-transitory computer readable medium of claim 8, wherein the process further comprises removing or obscuring an association between each set of data indicative of voltage levels and a unique logical or physical feedback data port of the DC-DC voltage converter system.

12. The non-transitory computer readable medium of claim 8, wherein the process further comprises:
determining whether a measure of dispersion for each set of direct current levels measured during the time period exceeds a direct current dispersion threshold level; and
determining that the measure of dispersion for each set of direct current levels does not exceed the direct current dispersion threshold level, then repeating providing the constant DC voltage level, measuring during a time period the set of direct current levels and associating each set of direct current levels, and receiving at each logical or physical data port the set of data indicative of voltage levels.

13. The non-transitory computer readable medium of claim 8, wherein the process further comprises:
determining whether each resistance is within a predetermined range of resistances; and
determining that at least one resistance is not within the predetermined range of resistances, then repeating for each power output coupled to electrical conductors for which the resistance was determined to be not valid or for each of all power outputs, measuring during another time period a set of direct current levels and associating each set of direct current levels, receiving at each logical or physical data port the set of data indicative of voltage levels, determining the pair, and determining the resistance.

14. The non-transitory computer readable medium of claim 8, wherein correlation is one of: a correlation coefficient, a magnitude of the correlation coefficient, and a coefficient of determination.

15. A direct current (DC)-DC voltage converter system configured to determine a resistance of at least two sets of electrical conductors each of which whose first ends are electrically coupled to a unique power output of the DC-DC voltage converter system and whose radio ends are electrically coupled to a DC power input of a unique radio, comprising:
at least two DC power outputs each of which is configured to be coupled through unique electrical conductors, at radio ends of the unique electrical conductors, to a unique measurement sensor and electrically coupled to a unique radio;
at least two DC-DC voltage converters each of which is configured to provide DC power to a unique DC power output of the at least two DC power outputs;
at least two logical or physical feedback ports each of which is configured to be communicatively coupled to the unique measurement sensor; and
processing circuitry communicatively coupled to each DC-DC voltage converter, and configured to:
cause provision of a constant direct current (DC) voltage level at each of at least two DC power outputs;
receive a set of direct current levels measured during a time period and drawn from each power output which provides a constant DC voltage level, and associating each set of direct current levels with a power output from which direct current was drawn;
receive, from each logical or physical data port, a set of data indicative of voltage levels measured during the time period at radio ends of a unique set of electrical conductors through which DC electrical power is provided from one of the at least two power output and through the first ends to the radio ends of the unique set of electrical conductors;
determine at least two pairs, wherein each pair includes (i) a unique set of data indicative of voltage levels measured during the time period and (ii) a unique set of direct current levels, and wherein each pair has a largest correlation of a set of correlations whose correlations are determined for the unique set of data indicative of voltage levels with respect to all sets of direct current levels or for the unique set of current levels with respect to all sets of data indicative of voltage levels; and
for each of the at least two pairs, (a) performing linear regression on the unique set of direct current levels and the unique set of data indicative of voltage levels of a pair, and then (b) determining, from a slope coefficient, or a magnitude thereof, derived from the linear regression, a resistance of a set of electrical conductors electrically coupled to a power output with which the unique set of direct current levels was drawn.

16. The DC-DC voltage converter system of claim 15, wherein the constant DC voltage level provided at each of at least two power outputs are different.

17. The DC-DC voltage converter system of claim 15, wherein the set of data indicative of voltage levels comprises voltage levels.

18. The DC-DC voltage converter system of claim 15, wherein the processing circuitry is further configured to remove or obscure an association between each set of data indicative of voltage levels and a unique logical or physical feedback data port of the DC-DC voltage converter system.

19. The DC-DC voltage converter system of claim 15, wherein the processing circuitry is further configured to:
determine whether a measure of dispersion for each set of direct current levels measured during the time period exceeds a direct current dispersion threshold level; and
determining that the measure of dispersion for each set of direct current levels does not exceed the direct current dispersion threshold level, then repeat providing the constant DC voltage level, measuring during a time period the set of direct current levels and associating each set of direct current levels, and receiving at each logical or physical data port the set of data indicative of voltage levels.

20. The DC-DC voltage converter system of claim 15, wherein the processing circuitry is further configured to:
determine whether each resistance is within a predetermined range of resistances; and
determining that at least one resistance is not within the predetermined range of resistances, then repeating for each power output coupled to electrical conductors for which the resistance was determined to be not valid or for each of all power outputs, measuring during another time period a set of direct current levels and associating each set of direct current levels, receiving at each logical or physical data port the set of data indicative of voltage levels, determining the pair, and determining the resistance.

21. The DC-DC voltage converter system of claim 15, wherein correlation is one of: a correlation coefficient, a magnitude of the correlation coefficient, and a coefficient of determination.

22.-64. (canceled)
